(19) United States
(12) Patent Application Publication
(10) Pub. No.: US 2026/0206620 A1
(43) Pub. Date: Jul. 16, 2026

(54) GLASS VIA FILLING

(71) Applicant: Kuprion Inc., Waterbury, CT (US)

(72) Inventors: Alfred A. Zinn, San Jose, CA (US); Khanh Nguyen, San Jose, CA (US); Hannah Thanh Zinn, Palo Alto, CA (US); Nicholas Antonopoulos, San Jose, CA (US)

(21) Appl. No.: 19/022,407

(22) Filed: Jan. 15, 2025

(51) Int. Cl. H01L 23/498; H01L 21/48; H01L 23/15

(52) U.S. Cl. CPC H10W 70/635; H10W 70/098; H10W 70/65; H10W 70/66; H10W 70/692

(57) ABSTRACT

A glass substrate comprising one or more openings therein. The glass substrate may be a glass interposer substrate usable in 2.5D and 3D packaging solutions. The one or more openings include one or more through-glass vias and the one or more openings are metallized with a bulk copper matrix formed from fusion of metal nanoparticles or a reaction product formed from metal nanoparticles to provide an electrical connection.

### FIELD OF THE INVENTION

The disclosure relates to the field of semiconductors, and more particularly to metallized glass substrates, including metallized glass interposer substrates for use in 2.5D and 3D packaging solutions.

### BACKGROUND OF THE INVENTION

There is a high demand for miniaturization, multifunctional and connected devices including smartphones, wearables, and Internet of Things (IoT), which has led to increased demand for high density and high band width. As a result, there have been efforts to expand semiconductor chips vertically, including both two-and-a-half-dimensional (2.5D) and three-dimensional (3D) integration, which typically require the use of an interposer to interconnect two or more semiconductor chips within a single package.

Chiplets are small, modular chips serving a specific function, such as CPUs or GPUs that can be mixed and matched into a complete system. This approach provides flexibility to compose a system cost-effectively and with increased efficiency and performance. In addition, due to their modular design, outdated chiplets can be easily and more frequently updated. By using chiplets, a large and complex system-on-chip (SoC) design can be divided into smaller chiplets that are linked together to building a system for specific applications.

In 2.5D integration, chiplets are connected via an interposer and two or more chiplets are placed closely together (i.e., less than about 50 μm apart) on a common interposer. The chiplets are placed on top of the interposers using small solder bumps to create electrical and mechanical connections. The finer the pitch between these bumps, the faster and more stable the connection.

The term “interposer” is generally used to describe an intermediate layer in an integrated circuit (IC) package that sits between an IC substrate and two or more chiplets. More generally, the term “interposer” refers to any structure that extends or completes the electrical connection between two or more electronic devices. Thus, the interposer may provide signal routing, power distribution, and thermal management for an IC dice in the package and interposers can be used to develop the heterogeneous integration of multiple ICs on a single platform/package. Interposers also allow for a greater density of ICs on a package or board, especially when it comes to extremely small input/output (I/O) pitch and line spacing. High-performance applications require these interposer technologies to have high I/Os at an extremely fine pitch, high dimensional stability, extremely low warpage, high temperature stability, and low coefficient of thermal expansion (CTE) mismatch.

The primary function of the interposer is to provide interconnectivity, so that the two or more semiconductor chips may employ high terminal pitch, and also to avoid the need for vias through the semiconductor chips themselves. FIG. 3 depicts an example of a 2.5D package that includes a plurality of chiplets that are connected to terminals on a top side of the interposer and the opposite (i.e., bottom) side of the interposer is connected to the package substrate by way of suitable terminals, such as “Controlled Collapse Chip Connection” (C4) joints. The interposer is provided with through-vias so that electrical connections may be made from the terminals of the semiconductor chiplets on the top side of the interposer to the terminals of the package substrate at the bottom side of the interposer.

In applications such as high-performance computing, a higher level of system integration may use a 3D packaging system. In a 3D system, multiple semiconductor dies are stacked vertically to create a three-dimensional architecture. That is, instead of establishing sideway connections, chiplets are stacked on top of each other to form a 3D system-on-chip (SoC). This approach does not add additional blocks but instead co-designs the chiplets together so that they operate as if they would be the same chip. 2.5D and 3D systems and solutions may also be used in combination to create high level 3D packaging solutions.

Interposers typically comprise a thin layer of silicon, glass, or other dielectric material having a plurality of through-hole vias (and optionally a plurality of blind vias) that are metalized to create a connection between a first circuit plane (i.e., top surface of the interposer) and a second circuit plane (i.e., bottom surface of the interposer). Fabricated holes in the interposer are typically very small, for example, on the order of 5 μm to 100 μm in diameter and 50 μm to 500 μm in depth and the number of holes per square centimeter may be in the hundreds (or even thousands). Once the holes are fabricated, the holes are metallized to provide an electrically conductive pathway between the first circuit plane and the second circuit plane.

As shown in FIG. 3, a 2.5D system allows for the integration of multiple chiplets (also referred to as “tiles”) on the interposer with different technology nodes where the chiplets are placed side-by-side on top of the interposer and are connected (for example) through a redistribution layer RDL or other metal layer or material to provide lateral connections between chiplets and distribute power from an external power source.

Silicon is one of the most common types of interposers due to its potential for high I/O density and established manufacturing processes. Silicon interposers are effective for use in 2.5D and 3D IC packaging systems and solutions to integrate logic and memory devices within the same platform. Silicon interposers utilize through silicon vias (TSVs) in 2.5D and 3D packaging systems and solutions to achieve high feature and I/O density. Metalized vias in the interposer provide a conductive path through the interposer for electrical signals to be transmitted from a first circuit plane to a second circuit plane of the interposer.

However, while silicon interposers are capable of achieving vertical integration of semiconductor chips, they can present problems, particularly in terms of mismatches in coefficients of thermal expansion (CTEs) through the stack, including CTE match-up between the silicon interposer and the organic package substrate. Undesirable CTE mismatches may result in failures in the interconnections between the semiconductor chips and the silicon interposer and/or failures in the interconnections between the silicon interposer and the package substrate. In addition, silicon interposers may suffer from high dielectric loss due to the semiconducting property of silicon. Silicon interposers also face reliability challenges related to TSVs and thermal management and can also add substantial expense to the overall package.

Organic interposers (e.g., Flame Retardant 4 (FR4)) have been introduced. They are more flexible than silicon and glass interposers, making them suitable for certain applications such as logic-memory integration, large CPUs, GPUs, and specific types of ASICs. However, they face problems in terms of lower I/O density and mechanical limitations due to their flexibility, as well as thickness/flatness (i.e., not thin enough/not flat enough) and processing constraints.

Glass interposers have been suggested as an alternative to silicon interposers due to their potential for higher interconnect density at a lower cost. Glass interposers can be advantageous in applications requiring ultra-high I/O pitch density, including, for example, high-bandwidth memory (HBM), high-performance computing, and optoelectronics-based computing. Glass interposers also possess superior mechanical, physical and optical properties that allow for more transistors to be connected in a package, providing better scaling and enabling assembly of larger chiplet complexes as compared to organic substrates. In addition, system designers may also have the ability to pack more chiplets in a smaller footprint on one package, while achieving performance and density gains with greater flexibility and lower overall cost and power usage.

Increasing demands for bandwidth in high performance computing, Fifth-generation (5G) communication, and Internet of Things (IOT) applications have driven the migration to 2.5D and 3D interposers, requiring less high frequency loss and higher ratio of hole depth/dimension for vertical interconnections making the need for through-glass vias with high aspect ratios. There is also demand for large number of closely positioned and high density vias. To obtain high density of through-glass vias on the same area requires that each through-glass via takes minimal space.

Glass as a substrate material is believed to be highly advantageous for electrical signal transmission because of its good dimensional stability, closely matched and tunable CTE, low electrical loss at high frequencies, high thermal stability, high electrical resistivity, and ability to be formed into various thicknesses and panel sizes.

However, glass interposers face several manufacturing challenges including, for example, surface defects, lower thermal conductivity compared to silicon, and limitations in achievable effective diameters for through-glass vias (TGVs). In addition, the metallization of the vias of glass substrates to provide electrically conductive pathways has proven to be difficult and inconsistent. Conductive metals such as copper do not adhere well to glass, including both the primary planar surfaces and the sidewall surfaces of the through-hole vias. Without being bound by theory, it is believed that the poor bonding of the conductive metal to glass is a result of the difference in the type of bonds that hold metal together on one hand and glass together on the other. The bonding mechanism of glass is fundamentally different from the bonding mechanism of metal and therefore limits adhesion between metals and glass.

Adherence of the conductive metal to glass can potentially be alleviated by roughening the glass surface to which the metal is to be bonded to provide for mechanical interlocking between the metal and the glass. However, roughening glass surfaces can cause additional problems that make that approach less than ideal and tend to produce a poor product. Accordingly, a new approach to solve problems associated with metalizing through-glass vias in glass substrates, including glass substrates intended to be used as interposers, and more generally in adhering conductive metal to glass substrates, is needed.

Current methods for metalizing TGVs and blind vias in glass interposers can be costly, time consuming, and may also lack manufacturing scalability. These metallization methods may include a combination of pressure vapor deposition (PVD) or sputtering deposition to form a seed layer followed by copper electroplating. Another means of depositing copper or other conductive materials into via holes in interposer substrates involves the use of metallic inks, which are typically formulated using metal powder dispersed in a bonding resin or other polymer for ease of hole filling and a capping agent to prevent the metallic powder from oxidizing. After the holes are filled with the metallic ink along with the resin or capping agents it is necessary to volatize all organic materials and remove them from the metallic powder to achieve reasonable electrical conductivity. Temperatures required for volatizing these organic compounds may reach 400° C. to 500° C. and the carbon ash left after volatizing the organic compounds may have a negative effect on the optimal conductivity and leave significant potential for discontinuous filling of the hole. In addition, many of these metallization processes work only on a very limited hole length/width ratio, making them very difficult to manufacture in a consistent manner.

U.S. Pat. No. 11,798,815 to Brown et al., the subject matter of which is herein incorporated by reference in its entirety, describes a method of manufacturing a glass article that requires a specific glass composition in combination with a two-step process of forming a first layer of a first metal on the glass substrate which is subjected to a first thermal treatment and then forming a second layer of a second metal on over the first layer followed by a second thermal treatment.

U.S. Pat. No. 9,691,634 to Koelling, the subject matter of which is herein incorporate by reference in its entirety, describes a method of creating electrically or thermally conductive vias in a dielectric material that includes the steps of depositing a powder comprising metal particles on a planar surface of the dielectric material and drying the deposited powder of metal particles to fill the vias.

However, both of these methods require multi-step processes and there are difficulties in utilizing these processes to metallize through-glass vias and blind vias in a glass interposer in a consistent matter, especially for very small diameter through-glass vias or through-glass vias with high aspect ratios.

Thus, it would be desirable to provide an improved method of metallizing glass interposers for use in advanced packaging solutions that overcomes the deficiencies of the prior art.

### SUMMARY OF THE INVENTION

It is an object of the present invention to provide a glass interposer or glass substrate that has high temperature tolerance.

It is another object of the present invention to provide a glass interposer for use in 2.5D and 3D packaging systems.

It is still another object of the present invention to provide a glass interposer or glass substrate containing a high density of glass vias.

It is still another object of the present invention to provide a method of metallizing a glass interposer or glass substrate having multiple apertures of different sizes and shapes that can be completely metallized at the same time.

It is another object of the present invention to provide a metallized glass interposer or glass substrate that exhibits very high electrical performance and the lowest possible resistance.

It is still another object of the present invention to provide a method of metallizing apertures in a glass interposer or glass substrate with an optimized/low CTE.

It is still another object of the present invention to provide a method of metallizing apertures in a glass interposer or glass substrate with a CTE match between the glass interposer or glass substrate and the metallized aperture.

It is another object of the present invention to provide a metallized glass interposer or glass substrate that is at least substantially planar.

It is another object of the present invention to provide a metallized glass interposer or glass substrate with improved mechanical properties.

It is still another object of the present invention to provide a glass interposer or glass substrate comprising a high density of small diameter through-glass vias and/or blind vias.

It is still another object of the present invention to provide a glass interposer or glass substrate comprising small diameter through-glass vias and/or blind vias metallized with copper.

It is still another object of the present invention to provide a glass interposer or glass substrate comprising small diameter through-glass vias and/or blind vias filled with a fused and/or consolidated copper nanoparticle paste.

It is still another object of the present invention to provide a glass interposer or glass substrate comprising large power trenches filled with a fused and/or consolidated copper nanoparticle paste.

It is still another object of the present invention to provide a glass interposer or glass substrate comprising surface interconnect metallization connecting various through-hole vias printed using copper nanoparticle paste.

It is still another object of the present invention to provide a glass interposer or glass substrate in which the fused and/or consolidated copper nanoparticle paste in the through-glass vias and/or blind vias exhibits good adhesion to the glass interposer or glass substrate.

It is still another object of the present invention to provide a glass interposer or glass substrate with a low CTE.

It is still another object of the present invention to provide a glass interposer or glass substrate with a CTE that is close to (or that at least substantially matches) the CTE of copper.

To that end, in one embodiment, the present invention relates generally to a glass substrate comprising one or more openings therein, wherein the one or more openings comprise one or more through-glass vias, wherein the one or more openings are metallized with a bulk metal matrix formed from fusion of metal nanoparticles or a reaction product formed from metal nanoparticles.

In another embodiment, the present invention also relates generally to a method of making a metallized glass interposer for use in an integrated circuit packaging solution, the method comprising the steps of:
a) providing a glass substrate comprising a plurality of through-glass vias, blind vias, and/or other openings arranged therein;
b) applying a copper nanoparticle paste composition to the glass substrate to fill the plurality through-glass vias, blind vias, and/or other openings arranged therein with the copper nanoparticle paste composition; and
c) consolidating the copper nanoparticle paste composition to form a bulk copper matrix within the plurality of through-glass vias, blind vias, and/or other openings, wherein the bulk copper matrix has a conductivity of at least 50% IACS (=2.90×10⁷ Siemens/m).

In another embodiment, the present invention relates generally to a packaging system comprising:
a) a substrate;
b) one or more glass interposers arranged on the substrate, wherein the one or more glass interposers are electrically connected to the substrate, wherein the one or more glass interposers comprises an array of metallized through-glass vias; and
c) a plurality of chiplets arranged on the one or more glass interposers, wherein the chiplets are electrically connected to the one or more glass interposers;
wherein the through-glass vias are metallized with a bulk matrix formed from at least partial fusion or consolidation of metal nanoparticles or a reaction product formed from metal nanoparticles.

### BRIEF DESCRIPTION OF THE FIGURES

The accompanying figures illustrate several aspects of the disclosure, and together with the description, illustrate various aspects of the present invention.

FIGS. 1 and 2 show diagrams of presumed structures of metal nanoparticles having a surfactant coating thereon.

FIG. 3 depicts a 2.5D package that includes a plurality of chiplets.

FIG. 4 depicts a first view of a glass interposer substrate comprising a plurality of through-glass vias in accordance with one aspect of the present invention.

FIG. 5 depicts a cross-section of a glass interposer substrate showing a through-glass via in accordance with one aspect of the present invention.

FIG. 6 depicts a first view of a glass interposer substrate comprising a plurality of large power trenches.

FIG. 7 depicts a first view of a glass interposer substrate comprising a plurality of surface interconnect traces connecting individual vias.

### DETAILED DESCRIPTION OF THE EMBODIMENTS

As described herein, the present invention relates generally to a glass substrate comprising one or more openings therein, which one or more openings may comprise through-glass vias, blind vias, conduits, trenches, and other openings wherein the one or more openings are metallized with a bulk matrix formed from the consolidation or fusion of conductive metal nanoparticles or a reaction product formed from conductive metal nanoparticles.

In one embodiment, the glass substrate comprises a trench that is metallized with the bulk matrix to provide direct electrical and/or mechanical connection between one or more chiplets and the glass substrate.

In another embodiment, the glass substrate comprises a glass interposer comprises one or more through-glass vias metallized with the bulk matrix and the chiplets are connected via the glass interposer to a substrate.

The present disclosure also relates generally to a packaging system comprising (a) a substrate; (b) one or more glass interposers arranged on the substrate, wherein the one or more glass interposers are electrically and mechanically connected to the substrate, wherein the one or more glass interposers comprise an array of metallized through-glass vias; and (c) a plurality of chiplets arranged on the one or more glass interposers, wherein the chiplets are electrically and/or mechanically connected to the one or more glass interposers.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

As used herein, “a,” “an,” and “the” refer to both singular and plural referents unless the context clearly dictates otherwise.

As used herein, the terms “comprises,” “comprising,” “includes” and/or “including” specify the presence of stated features, integers, steps, operations, elements, and/or components, but do not preclude the presence or addition of one or more other features, integers, steps, operations, elements, components, and/or groups thereof.

As used herein, the term “about” refers to a measurable value such as a parameter, an amount, a temporal duration, and the like and is meant to include variations of +/−15% or less, preferably variations of +/−10% or less, more preferably variations of +/−5% or less, even more preferably variations of +/−1% or less, and still more preferably variations of +/−0.1% or less of and from the particularly recited value, in so far as such variations are appropriate to perform herein. Furthermore, it is also to be understood that the value to which the modifier “about” refers is itself specifically disclosed herein.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

As used herein the term “substantially-free” or “essentially-free” if not otherwise defined herein for a particular element or compound means that a given element or compound is not detectable by ordinary analytical means that are well known to those skilled in the art of metal plating for bath analysis. Such methods typically include atomic absorption spectrometry, titration, UV-Vis analysis, secondary ion mass spectrometry, and other commonly available analytically methods.

As used herein, the term “metal nanoparticle” refers to metal particles that are about 300 nm or less in size, preferably about 200 nm or less in size, more preferably about 100 nm or less in size without particular reference to the shape of the metal particles.

As used herein, the term “micron-scale metal particles” refers to metal particles that are about 100 nm or greater in size, or at least about 300 nm or greater in size, or at least about 500 nm or greater in size in at least one dimension.

The terms “consolidate,” “consolidation” and other variants thereof are used herein interchangeably with the terms “fuse,” “fusion” and other variants thereof.

As used herein, the terms “partially fused,” “partial fusion,” and other derivatives and grammatical equivalents thereof refer to the partial coalescence of metal nanoparticles with one another. Whereas totally fused metal nanoparticles retain only minimal structural morphology of the original unfused metal nanoparticles (i.e., they resemble a dense bulk metal, but have grain boundaries in the 100-500 nm range), partially fused metal nanoparticles retain at least some of the structural morphology of the original unfused metal nanoparticles, such as a higher level of porosity, a smaller average grain size, and a higher number of grain boundaries. The properties of partially fused metal nanoparticles can be intermediate between those of the corresponding bulk metal and the original unfused metal nanoparticles. In some embodiments, fully dense (non-porous) bulk metal can be obtained as a monolithic metal body within a through-glass via by the processes described herein. In other embodiments, the bulk metal within a through-glass via can have less than about 10% porosity, or less than about 20% porosity, or less than about 30% porosity in an amount above full densification (i.e., >0% porosity). Thus, in particular embodiments, the bulk metal constituting the monolithic metal body may have a porosity ranging from about 2% to about 30%, or about 2% to about 5%, or about 5% to about 10%, or about 10% to about 15%, or about 15% to about 20%, or about 20% to about 25%, or about 25% to about 30%. In a particular example, a monolithic metal body having a uniform porosity of 12% may exhibit a thermal conductivity of 289 W/m·K.

In one embodiment, the present invention relates generally to a glass substrate, including a glass interposer substrate for electrically and mechanically coupling a plurality of chiplets to a packaging substrate. The glass substrate comprises one or more openings therein, which one or more openings may comprise through-glass vias, blind vias, conduits, trenches, and other similar openings, which are metallized with a bulk matrix formed from fusion of conductive metal nanoparticles or a reaction product formed from conductive metal nanoparticles. That is, in addition, to through-glass vias, the glass substrate may also comprise one or more additional openings, including one or more blind vias, along with one or more trenches or conduits, disposed therein. In some embodiments, the electrically conductive metal nanoparticles may include one or more of copper nanoparticles, silver nanoparticles, gold nanoparticles, and combinations of one or more of the foregoing. In one embodiment, the conductive metal nanoparticles comprises copper nanoparticles.

In one embodiment, the glass substrate comprises a trench that is metallized with the bulk matrix to provide direct electrical and/or mechanical connection between one or more chiplets and the glass substrate.

In one embodiment, the glass substrate has a first surface and a second surface, which are the primary surfaces of the glass substrate and face in generally opposite directions, and at least one through-glass via, preferably two or more through-glass vias, and more preferably a plurality of through-glass vias arranged in an array or other arrangement that covers at least a portion of the surface of the glass substrate. In one embodiment, the at least the portion of the glass substrate comprises an area or more than one area on which one or more chiplets are to be arranged. In addition, in one embodiment, the glass substrate may also optionally comprise one or more blind vias, trenches, apertures, or other openings arranged in the glass substrate. The one or more through-glass vias extend through the thickness of glass substrate as defined by a sidewall surface extending from the first surface to the second surface.

In one embodiment, the one or more through-glass vias, blind vias, trenches, apertures and/or other openings may be of different sizes and/or different shapes. Thus, it is contemplated that the method described herein can be used to metallize these openings of different shapes and completely fill the openings with copper, irrespective of the size/shape of the openings all in one step. For example, the openings may have a cross-sectional shape that is substantially spherical, substantially oval, square, trapezoidal, etc. and combinations of two or more thereof. In addition, the openings may be of two or more sizes such as between 25 and 100 microns, between 50 and 250 microns, between 10 and 50 microns, and between 150 and 1,000 microns, by way of example not limitation. For trenches, the openings can be about 1 cm to about 10 cm long, 250 micron to about 3000 mm wide and about 100 micron to about 3 mm deep.

The inventors of the present invention have surprisingly discovered that the process described herein can beneficially rapidly fill a plurality of openings of different sizes and shapes in a glass substrate simultaneously and completely. Based thereon, it can be seen that the inventive process described herein is very different from electroplating processes for metallizing glass vias which generally require additional preparation steps and are unable to fill large size vias or vias of different sizes and/or shapes in the same process due to electroplating processes being deposition rate-limiting.

In some embodiments, the side walls of the vias and trenches can be metallized with a thin layer of a conductive metal such as copper, silver, gold, aluminum, by way of example and not limitation.

In some embodiments, metal interconnects and traces can be printed on the surfaces of the glass interposer of the vias and trenches connecting the various vias and trenches to each other as needed. The thin metal layers may comprise copper, silver, gold, aluminum, by way of example and not limitation.

In some embodiments, the glass substrate is a glass interposer for use in a 2.5D (or 3D) packaging system or solution. Glass interposer may be manufactured in various formats include, for example, in the form of a wafer or a panel and various thicknesses, including ultrathin variants, are possible. For example, in a fusion forming process of the glass interposer, a large formats (>1 m in size) may be produced. In addition to scaling glass substrate size, it is possible to provide glass interposers having a thickness of less than 1,000 μm, or less than 500 μm, or less than 300 μm or less than 100 μm to deliver an ultra-slim flexible glass interposer.

FIG. 4 depicts a glass substrate 100. The glass substrate 100 includes a first surface 102 and a second surface 104. The first surface 102 and the second surface 104 that are at least approximately parallel, and face in generally opposite directions.

In one embodiment, and as shown in FIG. 4, the glass substrate 100 has a composition that comprises aluminum oxide (Al₂O₃) or another metal oxide glass network former. In some embodiments, the glass substrate 100 is an alkaline earth aluminoborosilicate substrate, an alkali aluminosilicate glass substrate, an alkali aluminoborosilicate glass substrate, or an alkaline earth aluminoborosilicate glass substrate. In other embodiments, the glass substrate 100 is alkali-free, such as an alkali-free aluminoborosilicate glass substrate or an alkali-free aluminosilicate glass substrate. By “alkali-free,” what is meant is that the glass substrate 100 contains no purposeful amount of an alkali metal, such that any alkali metal in the glass substrate 100 exists only as an impurity in the composition. In some embodiments, the glass substrate 100 has a composition comprising (on an oxide basis): about 6 to about 15 mol % Al₂O₃; and about 60 to about 78 mol % SiO₂.

In some embodiments, the glass substrate 100 is made by a glass manufacturing system that uses a fusion process to fabricate glass sheets, which are then cut into the desired shape of the glass substrate 100. The fusion process forms the glass substrate 100 with an already uniform thickness, such as with a total thickness variation (TTV) of less than 1.0 μm. Accordingly, polishing or other finishing steps may not be required before use of the glass substrate 100 as an interposer. If the fusion process results in the glass substrate 100 being too thick, then the thickness of the glass substrate 100 can be thinned, for example by etching and polishing. In still other embodiments, the glass substrate 100 is made with a non-fusion process and then polished or etched to have the desired thickness. After the glass substrate 100 is made, the glass substrate 100 may be annealed to reduce residual stresses present in the glass substrate 100.

The glass substrate 100 has a thickness 106 that extends from the first surface 102 and the second surface 104. In embodiments, the thickness 106 is within the range of 25 μm to about 1 mm, although thinner or thicker thicknesses 106 are envisioned. For example, for the specific embodiments described herein, the thickness 106 of the glass substrate 100 may be in the range of about 50 μm, about 100 μm, about 200 μm, about 300 μm, about 400 μm, about 500 μm, about 600 μm, about 700 μm, about 800 μm, about 900 μm, about 1 mm, and any range using those values, such as within the range of 50 μm to 300 μm, and so on. In embodiments, the thickness 106 is within the range of 150 μm to 500 μm, preferably with in the range of about 180 μm to about 450 μm, or within the range of about 350 μm to about 400 μm. The glass substrate 100 can have any desired shape. In embodiments, the glass substrate 100 has a circular shape. In those embodiments, the glass substrate 100 can have a diameter within the range of 200 mm to 300 mm. In other embodiments, the glass substrate 100 has a square or rectangular shape. In other embodiments, the specific interposer size is typically square or rectangular and can be 1-10 mm on one side or 5-20 mm in size for example. There are no fundamental limitations.

At low thicknesses (i.e., below about 250 μm), the glass interposer can become more flexible and there may be more issues with respect to process conditions.

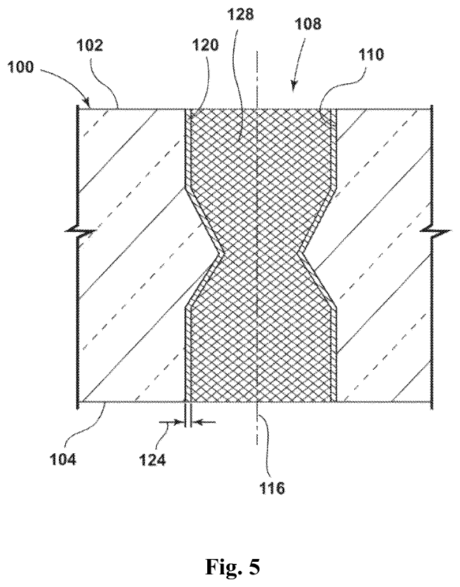

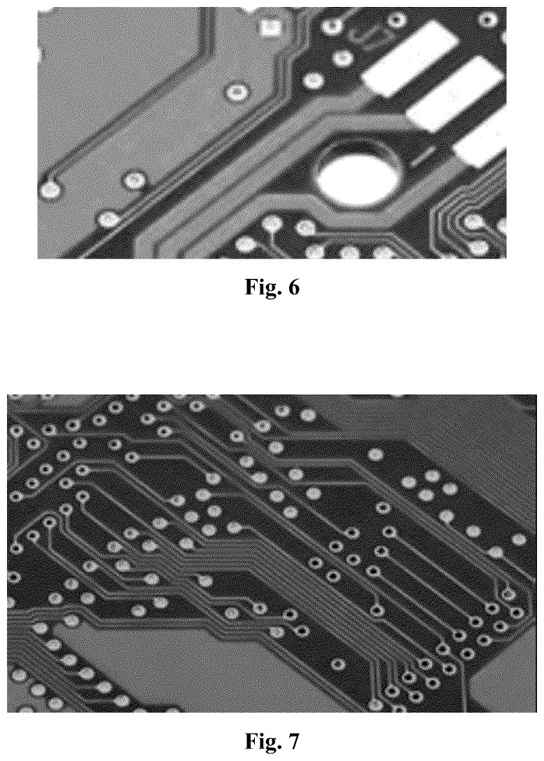

As shown in FIG. 5, the glass substrate 100 may further include one or more vias 108 that are metallizable with copper in the manner described herein. In embodiments, the glass substrate 100 includes a plurality of vias 108. In embodiments, some or all of the one or more vias 108 extend through the thickness 106 of the glass substrate 100 from the first surface 102 to the second surface 104. Such vias 108 may be referred to herein as “through-glass vias.” In other embodiments, some or all of the one or more vias 108 are open to the first surface 102 but extend only partially through the thickness 106, not extending all the way through the thickness 106 to the second surface 104. Such vias 108 may be referred to herein as “blind vias.” In embodiments, the glass substrate 100 includes a plurality of both through-glass vias and blind vias. A sidewall surface 110 defines each via 108 of the glass substrate 100.

Each via 108 has a diameter 112. Although the diameters 112 of each via 108 are shown as being the same, such need not be the case, i.e., the diameters 112 of the vias 108 may vary within the same glass substrate 100. In embodiments, the diameter 112 is within the range of from 5 μm to 150 μm. In some embodiments, the vias 108 have an hourglass shape with a waist 114 where the diameter 112 of the via 108 is less than the diameter 112 of the via 108 at the first surface 102 and second surface 104 of the glass substrate 100. In other embodiments, the vias 108 have a substantially cylindrical, tapered cylindrical, or substantially conical shape.

Each via 108 has a central axis 116. The central axis 116 of one via 108 is separated from the central axis 116 of an adjacent via 108 by a distance referred to as a pitch 118. The pitch 118 can be any value according to the desired application, such as, without limitation, about 10 μm to about 2000 μm, including about 10 μm, about 25 μm, about 50 μm, about 100 μm, about 250 μm, about 500 μm, about 1000 μm, about 2000 μm, or any value or range between any two of these values (including endpoints). For example, the pitch 118 can be within the range of about 10 μm to about 100 μm, about 25 μm to about 500 μm, about 10 μm to about 1000 μm, or about 250 μm to about 2000 μm.

In addition, in one embodiment, the pitch 118 is substantially the same as the largest diameter of the through-glass vias 108. That is, if the pitch 118 is about 10 μm or about 25 μm, each of the through-glass vias 108 has a largest diameter of about 10 μm or about 25 μm, respectively. Or in other words, the distance edge to edge of the vias can be as small as 10 microns. Larger diameter vias dictate large pitches, which can be substantially smaller than the via diameter itself. The pitch 118 on the same glass substrate 100 can be variable or can be consistent. The pitch 118 can be such that there are from one (1) to twenty (20) vias 108 per square millimeter, for example. The number of vias per unit of area will depend upon the design and application of the glass substrate 100. In embodiments, the vias 108 are patterned throughout the glass substrate 100. In other embodiments, the vias 108 do not form a pattern.

Vias 108 may be formed within the glass substrate 100 using one of a variety of forming techniques. For example, the vias 108 can be formed by mechanical drilling, chemical etching, laser ablation, laser assisted processes, laser damage and etching processes, abrasive blasting, abrasive water jetting machining, concentrated electron-thermal energy, or any other suitable forming technique. In the laser damage and etching process, a damage track is initially formed in the glass substrate 100 by using a laser to modify the glass substrate 100 along the damage track. An etching solution is then applied to the glass substrate 100. The glass substrate 100 is thinned by the etching solution. Because the etching rate of the glass substrate 100 is faster at the damage track, the damage track is preferentially etched so that a via 108 is opened through the glass substrate 100.

In one embodiment, through-hole glass vias are formed in the glass interposer using a combined laser and etching technology using laser induced etching. The laser introduces a modification in the glass, weakening the glass structure in predefined areas. This allows increased etching rates in these modified areas in comparison to surrounding material. One of the benefits of this process is that it does not create any cracks in the glass, allowing through-glass vias and blind vias to be formed in glass. Advanced laser processing and etching techniques enable the creation of very high aspect ratios.

Once the through-glass vias are formed within the glass substrate, the through-glass vias are metallized by filling the through-glass vias with a conductive nanoparticle paste composition, which may be a conductive metal nanoparticle paste composition, preferably a copper nanoparticle paste composition as further described herein. This conductive copper nanoparticle paste composition may be consolidated to form a bulk copper matrix within each through-glass via that is highly conductive.

In various embodiments, the metal nanoparticles used in the metal nanoparticle paste compositions can be about 20 nm or less in size. In other various embodiments, metal nanoparticles may be up to about 75 nm in size or up to 300 nm in size. In some embodiments, the metal nanoparticles within this size range may constitute between about 65% to about 95% by weight of the metal nanoparticle paste composition. As discussed above, metal nanoparticles in this size range have fusion temperatures that are significantly lower than those of the corresponding bulk metal and readily undergo consolidation with one another as a result. In some embodiments, metal nanoparticles that are about 20 nm or less in size can have a fusion temperature of about 220° C. or below (e.g., a fusion temperature in the range of about) or about 200° C. or below or between about 140° C. to about 220° C. or between about 145° C. and about 190° C. or between about 150° C. and about 180° C., which can provide advantages that are noted above.

In some embodiments, at least a portion of the metal nanoparticles can be about 10 nm or less in size, or about 5 nm or less in size. In some embodiments, the metal nanoparticles within this size range may constitute between about 5 to about 35% by weight of the metal nanoparticle paste composition. In more specific embodiments, at least a portion of the metal nanoparticles can range from about 1 nm in size to about 20 nm in size, or from about 1 nm in size and about 10 nm in size, or from about 1 nm in size to about 5 nm in size, or from about 3 nm in size to about 7 nm in size, or from about 5 nm in size to about 20 nm in size. In some embodiments, substantially all of the metal nanoparticles can reside within these size ranges. In some embodiments, larger metal nanoparticles can be combined in the metal nanoparticle paste compositions with metal nanoparticles that are about 20 nm in size or less. For example, in some embodiments, metal nanoparticles ranging from about 1 nm to about 10 nm in size can be combined with metal nanoparticles that range from about 25 nm to about 50 nm in size, or with metal nanoparticles that range from about 25 nm to about 100 nm in size, or 50 nm to about 150 nm or 50 nm to about 250 nm. As further discussed below, micron-scale metal particles and/or nanoscale particles can also be included in the metal nanoparticle paste compositions in some embodiments. Although larger metal nanoparticles and micron-scale metal particles may not be liquefiable at the low temperatures of their smaller counterparts, they can still become consolidated upon contacting the smaller metal nanoparticles that have been liquefied at or above their fusion temperature, as generally discussed above.

In addition to metal nanoparticles and organic solvents, other additives can also be included in the metal nanoparticle paste compositions such as, for example, rheology control aids, thickening agents, micron-scale conductive additives, nanoscale conductive additives, CTE adjusters, and any combination thereof. Chemical additives can also be present. As discussed hereinafter, the inclusion of micron-scale conductive additives, such as micron-scale metal particles, can be particularly advantageous.

In some embodiments, the paste compositions can contain about 0.01% to about 15% micron-scale (or near micron-scale) metal particles by weight, or about 1% to about 10% micron-scale (or near micron-scale) metal particles by weight, or about 1% to about 5% micron-scale (or near micron-scale) metal particles by weight, or about 0.1% to about 35% micron-scale (or near micron-scale) metal particles by weight, or about 5% to about 60% micron-scale (or near micron-scale) metal particles by weight. Inclusion of micron-scale (or near micron-scale) metal particles in the metal nanoparticle paste compositions can desirably reduce the incidence of cracking that occurs during consolidation of the metal nanoparticles when forming a monolithic metal body in a via. Without being bound by any theory or mechanism, it is believed that the micron-scale metal particles can become consolidated with one another as the metal nanoparticles are liquefied and form a transient liquid coating upon the surface of the micron-scale metal particles. In some embodiments, the micron-scale metal particles can range from about 500 nm to about 10 microns in size in at least one dimension, or from about 500 nm to about 10 microns in size in at least one dimension, or from about 100 nm to about 5 microns in size in at least one dimension, or from about 100 nm to about 15 microns in size in at least one dimension, or from about 100 nm to about 1 micron in size in at least one dimension, or from about 1 micron to about 10 microns in size in at least one dimension, or from about 5 microns to about 15 microns in size in at least one dimension, or from about 1 micron to about 50 microns in size in at least one dimension. The micron-scale metal particles can contain the same metal as the metal nanoparticles or contain a different metal. Thus, metal alloys can be fabricated by including micron-scale metal particles in the paste compositions with a metal differing from that of the metal nanoparticles. Metal alloys may also be formed by combining different types of metal nanoparticles with one another. Suitable micron-scale metal particles can include, for example, Cu, Ni, Al, Fe, Co, Mo, Ag, Zn, Sn, Au, Pd, Pt, Ru, Mn, Cr, Ti, V, Mg or Ca particles. In some embodiments, the micron-scale metal particles can be in the form of metal flakes, such as high aspect ratio copper flakes, for example. Thus, in some embodiments, the metal nanoparticle paste compositions described herein can contain a mixture of copper nanoparticles and high aspect ratio copper flakes or another type of micron-scale copper particles. Specifically, in some embodiments, the metal nanoparticle paste compositions can contain about 30% to about 90% copper nanoparticles by weight and about 0.01% to about 15% or 1% to 35% high aspect ratio copper flakes by weight.

In some embodiments, nanoscale conductive additives can also be present in the metal nanoparticle paste compositions. These additives can desirably provide further structural stabilization and reduce shrinkage during metal nanoparticle consolidation. Moreover, inclusion of nanoscale conductive additives can increase electrical and thermal conductivity values that can approach or even exceed that of the corresponding bulk metal following nanoparticle consolidation, which can be desirable for promoting heat transfer according to the disclosure herein. In some embodiments, the nanoscale conductive additives can have a size in at least one dimension ranging from about 1 micron to about 100 microns or ranging from about 1 micron to about 50 microns or from about 0.5 microns to about 25 micron in size. Suitable nanoscale conductive additives can include, for example, carbon nanotubes, graphene, nanodiamond, and the like. When present, the metal nanoparticle paste compositions can contain about 1% to about 20% or about 1% to about 10% nanoscale conductive additives by weight, or about 1% to about 5% nanoscale conductive additives by weight, or about 5% to about 15% conductive additives by weight.

Additional substances that can also optionally be present in the metal nanoparticle paste compositions include, for example, flame retardants, UV protective agents, antioxidants, carbon black, graphite, and the like.

In one embodiment, the inventors of the present invention have determined that the largest particle size of the metal nanoparticle paste composition capable of filling the through-glass via is dependent on the size of the through-glass vias and blind vias being filled. In one embodiment, a largest diameter of the through-glass via and blind vias being filled must be at least 4X greater in size than the diameter of the largest size particles in the nanoparticle paste composition or at least 5-10X. In one preferred embodiment, the ratio of the largest diameter of the vias (both through-glass vias and blind via) to the diameter of the largest size particles is at least about 4:1, preferably about 6:1, or about 10:1 or about 20:1.

The inventors of the present invention have discovered that the use of smaller through-glass vias allows for faster processing speeds of the packaging system. Based thereon, in one embodiment, it is also desirable that the through-glass vias have a high aspect ratio which may be about 4:1or about 6:1or about 8:1 or about 10:1 but can also be as low as 1:1 or 2:1 and even less.

As described herein, the relationship between the pitch of the through-glass vias and the largest diameter of the through-glass vias is an important aspect of the present invention. As described herein, in one embodiment the pitch of the through-glass vias is at least substantially the same as the largest diameter of the through-glass vias.

In some embodiments, it would be desirable to produce a glass substrate with through-glass vias having a largest diameter of about 100 μm or about 75 μm or about 50 μm or about 25 μm or about 10 μm or the like. In some embodiments, the glass substrate is a glass interposer that includes a plurality of through-glass vias having a largest of about 25 μm and a pitch of about 25 μm. In some embodiments, the glass substrate is a glass interposer that includes a plurality of through-glass vias having a largest of about 10 μm and a pitch of about 10 μm.

When metallizing such small through-glass vias with a conductive metal such as copper and, more particularly metallizing the through-glass vias with a bulk copper matrix formed from fusion of copper nanoparticles or a reaction product formed from copper nanoparticles, different processing requirements may be required in order to provide a metallized through-glass via that is highly conductive and defect free. For via diameters of 500 micron or more, the separation should be ½ or more of the respective via diameter. For via diameters smaller than that, the separation can be as low as 10 micron.

As described herein, in order to fully metallize the through-glass vias with a deposit that is highly conductive and defect free, in one embodiment, all (or substantially all) of the particles in the copper nanoparticle paste composition must have a largest dimension that is within a defined range. When filling the through-glass vias described herein, depending on the diameter of the through-glass vias being filled, largest size particles (e.g., micron-sized copper powder of about 1-5 microns) are used in the copper nanoparticle paste composition, which helps to keep the density at the desired level and reduce shrinkage.

In one embodiment, in order to metallize through-glass vias that are about 25 μm in size, the largest size particles must be less than about 5 μm, such as between about 500 nm and about 5 microns.

In one embodiment, in order to metallize through-glass vias that are about 10 μm in size, the largest size particles must be less than about 500 nm to 1.5 micron. However, in order to obtain larger size particles within this range the particles must either be sieved to remove larger size particles above this range, or alternatively, the process of making copper nanoparticles, as further described herein, must be optimized to make larger particles in situ.

To make bigger particles at the same time as the smaller copper nanoparticles in situ (i.e., particles in 2 separate size ranges—20-150 nm and 350-750 nm), the copper nanoparticles are processed in two separate batches to achieve the two particle sizes desired.

In addition, while platelets may be desirable in filling various apertures, including larger through-glass vias, blind vias, etc., when the through-glass vias have a largest diameter of 10 μm or less, copper platelets may not matter in the compositions described herein and copper particles in the form of copper nanospheres may perform just as well. These may or may not be amorphous. Above about 10 nm in diameter, they can be substantially crystalline with distinct crystal shapes and facets.

The one or more vias 108 of the glass substrate 100 are metalized pursuant to the method described herein. Although the method is described in the context of the glass substrate 100 as an interposer and for the purpose of metalizing the vias 108, it should be understood that the present invention is directed generally to a method of metallizing a glass substrate 100 intended for any purpose, and for metalizing surfaces other than the sidewall surface 110 of the vias 108, such as the first surface 102, the second surface 104, and/or other apertures or vias or openings through or within the glass substrate 100. In the context of the glass substrate 100 for use as an interposer, metalizing the vias 108 provides a conductive path through the interposer for electrical signals to pass from the first surface 102 to the second surface 104.

Filling of the vias with metal nanoparticles may take place by any suitable technique. Suitable techniques may include those in which the one or more vias are filled individually with metal nanoparticles, or those in which the one or more vias are filled substantially at the same time. In illustrative embodiments, syringes, syringe arrays, or other arrangements of dispensation devices containing the metal nanoparticle paste compositions may be used for filling the one or more vias. In other illustrative embodiments, printing techniques such as screen printing, stencil printing, or inkjet printing may be used to fill the one or more vias with the metal nanoparticle paste composition. In more specific embodiments, at least a portion of the one or more vias may be filled by screen printing the metal nanoparticle paste composition. Doctor blading techniques may also be utilized to fill one or more vias with a metal nanoparticle paste composition all at the same time or near the same time.

The technique for filling the vias may vary depending upon the size (diameter) of the vias. Automated dispensation into each via may take place in some embodiments, such as with a robotically operated syringe, optionally incorporating a syringe pump. Arrays of syringes or similar arrangements of dispensation devices may be used to fill multiple vias simultaneously or near simultaneously. As such, the vias may be filled one at a time in some embodiments, or multiple vias may be filled with the metal nanoparticle paste compositions at the same time, according to other embodiments. In some embodiments, each of the vias may be filled with the nanoparticle paste composition at the same time.

In addition or alternately, in some embodiments, the metal nanoparticle paste composition may have a density that is adjusted to minimize sagging, thereby aiding in retaining the nanoparticle paste composition within the one or more vias. In illustrative embodiments, the metal nanoparticle paste compositions may suitably have a density ranging from about 3.5 g/cm3 to about 6.5 g/cm3. Higher density values may be more desirable to minimize shrinking and cracking during metal nanoparticle consolidation. Micron-scale particles, typically in an amount of about 10 wt. % or more, up to about 35 wt. %, may aid in mitigating shrinkage during metal nanoparticle consolidation.

In one embodiment, the copper nanoparticle paste composition is applied to the glass substrate by a blade or squeegee that spreads the copper nanoparticle paste composition across at least a first surface of the substrate that spread or wipe the copper nanoparticle paste composition across the surface of the substrate and into the one or more through-glass vias, blind vias, and other openings. In one embodiment, the angle of the squeegee is no more than about 25 degrees, preferably about 5-10 degrees. In one embodiment, the squeegee comprises a non-reactive material such as polyester, polyvinyl chloride, silicone, or metal etc. In one embodiment, the copper nanoparticle paste composition is spread over at least the first surface of the substrate more than one time, and preferably multiple times to ensure that the through-glass vias, blind glass vias, and other openings are completely metallized. In addition, the step of squeegeeing may be performed on both sides of the glass substrate at least substantially simultaneously or in sequence. Thereafter, once the copper nanoparticle paste has been applied to the substrate, one or both sides of the substrate may be cleaned, such as by wiping, to remove any excess nanoparticle paste composition from the surfaces of the substrate. This is then followed by consolidation by at least one of heat or pressure to produce a bulk copper deposit within each of openings, including the through-glass vias, blind glass vias and other such openings.

In one embodiment the bulk copper deposit within each opening, including one or more through-glass vias, blind glass vias, and other openings has a porosity of less than about 30%, preferably less than 20%, more preferably less than 15% and most preferably less than about 10%.

In one embodiment, the bulk deposit within each through-glass via has a density of 5.4 g/cm³, preferably 6.5 g/cm³ more preferably 7.6 g/cm³ and most preferably more than 8.0g/cm³.

In one embodiment, the bulk deposit within each opening exhibits an electrical conductivity of about 35% International Annealed Copper Standard (IACS) (2.03×10⁷ Siemens/m) preferably 50% IACS (2.9×10⁷ Siemens/m), more preferably 60% IACS (3.48×10⁷ Siemens/m) or above. IACS refers to an empirically derived standard value for the electrical conductivity of commercially available copper. The standard is most often used as a comparative property in the specification of the conductivity of other metals, expressed as X% IACS, meaning that the metal has an electrical conductivity that is X% of the copper specified as the IACS standard. It is noted that 100% IACS is equivalent to a conductivity of 58.108 megasiemens per meter (MS/m) at 20° C. or a resistivity of 1/58.108 ohm per meter for a wire one square millimeter in cross section. IACS %=(172.41/resistivity) where resistivity, ρ, (ro) is in micro-ohms per centimeter.

In one embodiment, the grain size of the copper deposit is between about 350 to 650 nm. In one embodiment, the grain size of the copper deposit is between about 0.5 to 1.5 micron. In addition, it is highly desirable that the bulk copper deposit within each opening is at least substantially free, and preferably is completely free of any voids or cracks.

In one embodiment, the paste formulation is formulated to exhibit a density of between about 3.5 g/cm³ and about 5.5 g/cm³, preferably between about 4.5 cm³ and about 6.5 g/cm³. This allows the paste formulation to be used in a process that uses pressure processing, relying on pressure to fill the openings, including through-glass vias, blind glass vias, and other openings, with the copper nanoparticle paste composition described herein. At the same time, it is desirable that the paste formulation also exhibits a suitable viscosity, such as in the range of about 100,000 psi to about 2,000,000 psi. In other embodiments of the present invention, the copper nanoparticle paste formulation is thixotropic with a thixotropic index of 5 to as much as 20.

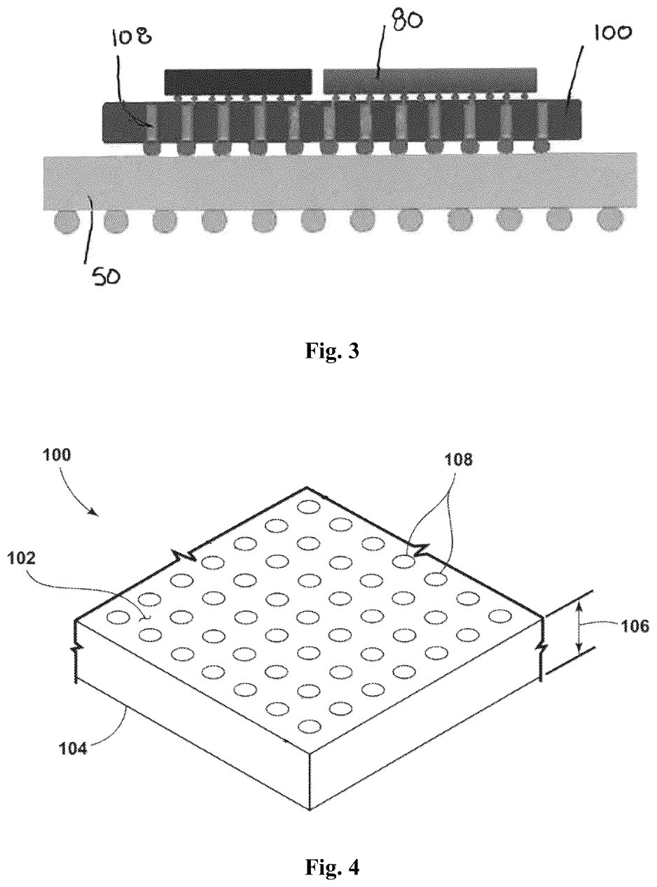

In one embodiment, the present invention also relates generally to a packaging system 40 as shown in FIG. 3 comprising:
a. a substrate 50;
b. one or more glass interposers 100 arranged on the substrate, wherein the one or more glass interposers 100 are electrically connected to the substrate 50 with one or more metallized through-glass vias 108; and
c. a plurality of chiplets 80 arranged on the one or more glass interposers 100, wherein the chiplets 80 are electrically connected to the one or more glass interposers 100;
wherein the through-glass vias 108 are metallized with a bulk matrix formed from at least partial fusion or consolidation of metal nanoparticles or a reaction product formed from metal nanoparticles.

In one embodiment, the present invention also relates generally to a method of making a metallized glass substrate, preferably a metallized glass interposer for use in an integrated circuit packaging solution, the method comprising the steps of:
a. providing a glass substrate comprising a plurality of through-glass vias, blind vias, and/or other openings arranged therein;
b. applying a copper nanoparticle paste composition to the glass substrate to fill the plurality through-glass vias, blind vias, and/or other openings arranged therein with the copper nanoparticle paste composition;
c. consolidating the copper nanoparticle paste composition to form a bulk copper matrix within the plurality of through-glass vias, blind vias, and/or other openings, wherein the bulk copper matrix is highly conductive.

In one embodiment, the step of applying the copper nanoparticle paste composition to the glass substrate is accomplished using a blade or squeegee to spread the copper nanoparticle paste composition over the glass substrate and into the openings arranged therein. It is contemplated that this step may be repeated one or more times to ensure that the through-glass vias, blind vias, and other openings are completely filled with the copper nanoparticle paste composition. In one embodiment, the openings comprise through-glass vias and the copper nanoparticle paste composition is applied at least substantially simultaneous or sequentially to both sides of the glass substrate to fill the through-glass vias from both sides.

In one embodiment, the copper nanoparticle paste composition is optimized to minimize shrinkage following consolidation. In one embodiment the copper nanoparticle paste composition is optimized to allow no more than about 20% shrinkage, preferably no more than about 10% shrinkage, which can be measured by laser profilometry. In one embodiment, the openings are overfilled to allow for some shrinkage of the consolidated copper nanoparticle paste composition. The excess is then polished off. In one embodiment, a final finish is applied to the top and bottom surfaces of the glass substrate to provide a final conductive finish on the metallized openings. In one embodiment, the final finish comprises a thin conductive layer, such as by electroless or electroless plating or using an ink deposition process. In one embodiment, the final conductive finish comprises a thin layer of copper that is deposited by electroplating or electroless plating.

In one embodiment, the step of consolidating the copper nanoparticle paste composition is accomplished at a temperature of between about 140° C. and about 230° C., or between about 145° C. and about 200° C., or between about 150° C. and about 190° C. The time period for consolidation will depend in part on the specific makeup of the copper nanoparticle paste composition. In one embodiment, the time period for consolidation is within the range of about 5 min to about 15 min without pressure. In another embodiment, the time period for consolidation is within the range of about 30-90 min with pressure (500 to 1000 psi).

In one embodiment, prior to the step of applying the copper nanoparticle paste composition to the glass substrate, the walls of the plurality of plurality through-glass vias, blind vias, and/or other openings are coated with a metal or metalloid to promote adhesion of the copper nanoparticle paste composition to the walls of the openings of the glass substrate. The metal coating may comprise a very thin (i.e., 100 nm to 2 micron) layer of copper, silver, tin, bismuth, gallium, zinc, combinations thereof, or another metal or metal alloy.

In one embodiment, the thin coating is formed from, copper, silver, tin, alloys thereof, or another similar metal or metal alloy and provides hermetic sealing between the two sides of the glass interposer.

In one embodiment, the CTE of the monolithic metal body formed from the copper nanoparticle paste composition is adjusted to at least substantially match the CTE of the glass substrate. That is, when the glass substrate has a high density of through-glass vias, blind vias, and other opening, the resulting glass substrate may contain more than 20% copper or more than 30% copper or more than 40% copper or up to 60% copper and it is necessary that the CTE of the monolithic metal body match the CTE of the glass substrate so as to prevent damage to the metallized glass substrate.

In another preferred embodiment, the present invention also relates generally to a method of making an integrated circuit packaging solution, the method comprising the steps of:
a. arranging one or more glass interposers on a substrate, wherein the one or more glass interposers comprise one or metallized through-glass vias, blind vias, or other vias disposed therein, wherein the glass interposers are metallized in accordance with the process described herein; and
b. arranging one or more chiplets on the one or more glass interposer;
wherein the one or more chiplets are electrically connected to the substrate through the one or more glass interposers.

As described herein, metal nanoparticle compositions can be used to fill openings, including through-glass vias, blind vias, trenches, conduits, apertures, and other similar structures to establish one or more electrically or thermally conductive pathways extending through a glass interposer or other similar glass substrate. The electrically or thermally conductive pathway formed from the metal nanoparticles may comprise a monolithic block of metal or a metal composite (equivalently referred to herein as a “monolithic metal block” or “monolithic metal body”) extending between the first and second faces of the glass interposer or other similar glass substrate and filling each through-glass via and other openings and/or apertures. Preferably, the monolithic metal block spans the entire cross-sectional profile of the via (i.e., filling the via), to promote electrical and thermal conduction. In contrast, wholly electrodeposition approaches can be difficult to perform and are at considerable risk of incomplete via filling and/or void formation, thereby leading to poor electrical and/or thermal conduction.

Metal nanoparticles are uniquely qualified for the applications described herein due to the moderate processing conditions needed for consolidating the metal nanoparticles together into a monolithic block of the corresponding bulk metal. As described in further detail below, metal nanoparticles can be at least partially consolidated (fused) together into the corresponding bulk metal under a range of mild processing conditions that are significantly below the melting point of the metal itself. Due to copper's high thermal conductivity and relatively low cost, copper nanoparticles can be a particularly desirable type of metal nanoparticle for use in the various embodiments of the present disclosure. A monolithic block of copper formed within and filling a through-glass via may function much more effectively for promoting electrical conducting through the glass substrate.

In addition, if desired or needed, metal nanoparticle compositions may be further tailored to improve the electrical properties still further when filling vias or similar structures. In particular, the metal nanoparticle compositions may be tailored to meet different thermal expansion requirements and to reduce thermomechanical stress during operational hot-cold cycling. Metal nanoparticle compositions suitable for use in the present disclosure may contain larger, micron-size (micron-scale), highly thermally conductive particles (e.g., copper, diamond, carbon nanotubes, graphene, and the like) while still being easily dispensed by various via-filling techniques. Such additives may decrease the CTE of a monolithic metal body formed from copper nanoparticles down to about 10 ppm, or even as low as 3 ppm in some cases, as compared to a value of 17 ppm typically found for bulk copper.

This tunable CTE is an important aspect of the present invention and a low CTE is generally preferred. In one embodiment, it is desirable for the monolithic metal body to have a low CTE close to that of silicon (i.e., a CTE of about 3) or silicon carbide (i.e., a CTE of about 4.5). Therefore, in one embodiment, the copper paste formulation used to fill the through-glass vias has a CTE of between about 2 ppm and about 8 ppm, more preferably between about 2.5 ppm and about 7 ppm.

In various embodiments, the copper composite may be formed through consolidation of copper nanoparticles with micron-size copper particles and the CTE modifier. The copper nanoparticles, the micron-size copper particles, and the CTE modifier may define a copper nanoparticle paste composition, as described in more detail above. In some embodiments, suitable copper nanoparticle paste compositions may comprise about 30 wt. % to about 60 wt. % copper nanoparticles or about 5 wt. % to about 50 wt. % micron-size copper particles, and an effective amount of the CTE modifier to target a specified CTE. The CTE modifier may be present in an amount ranging from about 1% to about 35% by weight, or about 4% to about 8% by weight, or about 5% to about 15% by weight, or about 10% to about 20% by weight. Exemplary guidance of how to select particular CTE modifiers and amounts thereof to achieve specified CTE values in a copper composite are provided hereinbelow. The micron-size copper particles may be omitted in some embodiments.

Suitable CTE modifiers may include, but are not limited to, diamond particles, graphite/pitch-based carbon fibers (e.g., having a diameter of about 10 microns), tungsten particles, molybdenum particles, diamond particles, boron nitride particles, boron carbide particles, aluminum nitride particles, silicon, carbon nanotubes, graphene, the like, and any combination thereof. Carbon-based additives, for example, can achieve about 2-3 ppm thermal expansion when added at about 16% by volume, or about 7 ppm thermal expansion when added at about 9% by volume, or about 6 ppm when added at about 11% by volume.

Adding diamond at about 45% by volume can achieve about 5-6 ppm thermal expansion depending on density (82%). At about 37% loading by volume and 93% density, the thermal expansion provided by diamond may be about 6 ppm. At a diamond loading of more than about 50% by volume, the thermal expansion drops below about 5 ppm.

Consolidated copper nanoparticles by themselves exhibit a thermal expansion of about 7-12 ppm depending on the process conditions and density. With increasing density, the thermal expansion approaches that of bulk copper (17 ppm). At about 91% density, the thermal expansion is about 7-8 ppm, and at about 93% density the thermal expansion increases to about 10-11 ppm. At about 98% density, the thermal expansion reaches about 15 ppm. Even at such high density values, the thermal expansion is still below the value for bulk copper, which is presumed to arise from the nanoporosity present following copper nanoparticle consolidation.

Addition of micron-scale metal particles to metal nanoparticles (e.g., copper nanoparticles) can increase the thermal expansion to reach 17 ppm and beyond depending on the specific metal. Addition of aluminum particles, for example, having a bulk CTE of about 23-24 ppm, can increase the CTE of the resulting composite to a value exceeding that of bulk copper. Addition of about 55% micron-scale copper powder results in a thermal expansion of about 14 ppm at a density of 96%.

Carbon nanotubes may increase the thermal conductivity of copper up to about 600 W/m·K from a value in the low 400 s W/m·K for bulk copper alone. The degree of thermal conductivity modification achievable with carbon nanotubes may depend upon the length of the carbon nanotubes, with longer carbon nanotubes exceeding a thermal conductivity value of about 600 W/m·K. Such modification of the thermal conductivity may occur in concert with CTE modification in the manner discussed above.

Once metal nanoparticle consolidation occurs, the resulting bulk metal binds the micron-scale additives together to form a monolithic metal body extending through the glass substrate, thereby providing a thermally conductive pathway through the substrate. The monolithic metal body may comprise a composite material depending on the nature of the micron-scale particles. Additional tailoring of a metal nanoparticle composition to promote dispensation and/or consolidation of the metal nanoparticles may also be performed, as further described herein.

In one embodiment, in order to prevent any detachment or separation of the monolithic metal body from the walls of the through-glass via filled with the consolidated metal nanoparticles, a thin coating of a different metal may be plated upon walls of the via before or even after filling the via with metal nanoparticles. In the case of filling a via with copper nanoparticles, plating of the through-glass via walls with tin may significantly improve adherence of the monolithic metal body to the through-glass via walls. The tin is not believed to melt when processing the copper nanoparticles to form a monolithic metal body within the through-glass vias. Without being bound by any theory or mechanism, a tin-copper intermetallic compound is believed to form following copper nanoparticle consolidation in a tin-coated via, wherein the tin-copper intermetallic compound may promote stability against thermal cycling stresses that otherwise may afford detachment of the monolithic metal body. The tin is believed to provide a CTE mediator that may be better matched with that of the glass substrate. Other metals that provide CTE matching and/or readily form alloys or intermetallic compounds with copper around the fusion temperature of copper nanoparticles (~200° C.) may also be suitable in this regard. Once the alloy or intermetallic compound forms, no additional melting occurs during subsequent heating operations. The tin-copper intermetallic compound or alternative substance may undergo thermal cycling multiple times without significantly decreasing adherence to the through-glass via walls. Since only a thin tin layer needs to be deposited upon the via walls, plating may be performed conventionally and much more rapidly than approaches for wholly filling through-glass vias with electrodeposited metal. Alternative coating approaches may avoid electrodeposition altogether.

Before further discussing more particular aspects of the present disclosure, an additional description of metal nanoparticles and their processing conditions, particularly copper nanoparticles, is provided herein.

Metal nanoparticles exhibit a number of properties that can differ significantly from those of the corresponding bulk metal. One property of metal nanoparticles that can be of particular importance for processing according to the disclosure herein is nanoparticle fusion (consolidation) that occurs at the metal nanoparticles' fusion temperature. As used herein, the term “fusion temperature” refers to the temperature at which a metal nanoparticle liquefies, thereby giving the appearance of melting. As used herein, the terms “fusion” and “consolidation” synonymously refer to the coalescence or partial coalescence of metal nanoparticles with one another to form a larger mass, such as a monolithic metal body filling and extending through a through-glass via. Accordingly, there is at least partial connectivity between the metal nanoparticles following heating above the fusion temperature.

Upon decreasing in size, particularly below about 20 nm in equivalent spherical diameter, the temperature at which metal nanoparticles undergo liquefication drops dramatically from that of the corresponding bulk metal. For example, copper nanoparticles having a size of about 20 nm or less can have fusion temperatures of about 235° C. or below, or about 220° C. or below, or about 200° C. or below, or about 180° C. or below, or between about 140° C. to about 220° C., or between about 145° C. and about 200° C., or between about 150° C. and about 190° C., in comparison to bulk copper's melting point of 1083° C. Thus, the consolidation of metal nanoparticles taking place at the fusion temperature can allow structures containing bulk metal to be fabricated at significantly lower processing temperatures than when working directly with the bulk metal itself as a starting material. Processing conditions for consolidating metal nanoparticles may typically be between about 150° C. up to about 220° C., and 275-400 psi. However, pressure is not necessarily required for metal nanoparticle fusion to take place. More dense monolithic metal bodies may be obtained by applying pressure when promoting metal nanoparticle consolidation. Thus, metal nanoparticles, such as copper nanoparticles, provide a facile material for filling through-glass vias and other apertures in glass interposers and forming a monolithic block comprising bulk metal or a bulk metal composite within the through-glass vias without distorting, warping, or otherwise damaging the glass interposer.

A number of scalable processes for producing bulk quantities of metal nanoparticles in a targeted size range have been developed. Most typically, such processes for producing metal nanoparticles take place by reducing a metal precursor in the presence of one or more surfactants. The metal nanoparticles can then be isolated and purified from the reaction mixture by common isolation techniques and processed into a formulation suitable for dispensation into vias.

Any suitable technique can be employed for forming the metal nanoparticles used in the disclosure herein. Particularly facile metal nanoparticle fabrication techniques are described, for example, in U.S. Pat. Nos. 7,736,414, 8,105,414, 8,192,866, 8,486,305, 8,834,747, 9,005,483, 9,095,898, and 9,700,940, each of which is incorporated herein by reference in its entirety. As described therein, metal nanoparticles can be fabricated in a narrow size range by reduction of a metal salt in a solvent in the presence of a suitable surfactant system, which can include one or more different surfactants. Without being bound by any theory or mechanism, it is believed that the surfactant system can mediate the nucleation and growth of the metal nanoparticles, limit surface oxidation of the metal nanoparticles, and/or inhibit metal nanoparticles from extensively aggregating with one another prior to being at least partially fused together. Suitable organic solvents for solubilizing metal salts and forming metal nanoparticles can include, for example, formamide, N,N-dimethylformamide, dimethyl sulfoxide, dimethylpropylene urea, hexamethylphosphoramide, tetrahydrofuran, glyme, diglyme, triglyme, tetraglyme, proglyme, or polyglyme. Reducing agents suitable for reducing metal salts and promoting the formation of metal nanoparticles can include, for example, an alkali metal in the presence of a suitable catalyst (e.g., lithium naphthalide, sodium naphthalide, or potassium naphthalide) or borohydride reducing agents (e.g., sodium borohydride, lithium borohydride, potassium borohydride, or tetraalkylammonium borohydrides).

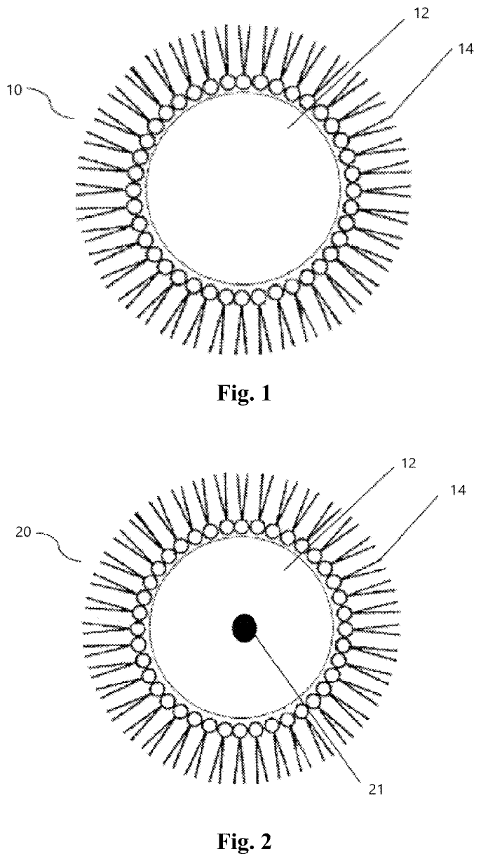

FIGS. 1 and 2 show diagrams of presumed structures of metal nanoparticles having a surfactant coating thereon. As shown in FIG. 1, metal nanoparticle 10 includes metallic core 12 and surfactant layer 14 overcoating metallic core 12. Surfactant layer 14 can contain any combination of surfactants, as described in more detail below. Metal nanoparticle 20, shown in FIG. 2, is similar to that depicted in FIG. 1, except metallic core 12 is grown about nucleus 21, which can be a metal that is the same as or different than that of metallic core 12. Because nucleus 21 is buried deep within metallic core 12 in metal nanoparticle 20 and is very small in size, it is not believed to significantly affect the overall nanoparticle properties. Nucleus 21 may comprise a salt or a metal, wherein the metal may be the same as or different than metallic core 12. In some embodiments, the nanoparticles can have an amorphous morphology.

As described herein, the metal nanoparticles have a surfactant coating containing one or more surfactants upon their surface, which can be formed on the metal nanoparticles during their synthesis. The surfactant coating is generally lost during consolidation of the metal nanoparticles upon heating above the fusion temperature, resulting in the formation of a monolithic metal body within the one or more through-glass vias, according to the various embodiments of the present disclosure. Formation of a surfactant coating upon metal nanoparticles during their syntheses can desirably limit the ability of the metal nanoparticles to fuse to one another prematurely, limit agglomeration of the metal nanoparticles, and promote the formation of a population of metal nanoparticles having a narrow size distribution. Porosity values may range from 2-30% following consolidation, which may be tailored based upon a number of factors, including the type of surfactant(s) that are present.

While various types of metal nanoparticles may be used, in one particularly preferred embodiment, the metal nanoparticles are highly electrically conductive metal nanoparticles that are capable of and configured to electrically connect a packaging substrate with a plurality of chiplets as further described herein. Suitable metal nanoparticles can include, but are not limited to, copper nanoparticles, silver nanoparticles, gold nanoparticles, and combinations thereof. Micron-scale particles of these metals can be present in metal nanoparticle paste compositions containing the metal nanoparticles as well. Copper can be a particularly desirable metal for use in the embodiments of the present disclosure due to its low cost, strength, and excellent electrical and thermal conductivity values. Adherence of copper to the walls of a through-glass via may be significantly enhanced through use of an electrodeposited coating, such as a coating comprising tin, as discussed further herein. Alternative coatings such as those comprising gallium, zinc and others may also be suitably used in this regard to promote adherence of a monolithic metal body to the via walls.

In various embodiments, the surfactant system present within the metal nanoparticles can include one or more surfactants. The differing properties of various surfactants can be used to tailor the properties of the metal nanoparticles. Factors that can be taken into consideration when selecting a surfactant or combination of surfactants for inclusion upon the metal nanoparticles include, for example, ease of surfactant dissipation from the metal nanoparticles during nanoparticle fusion, nucleation and growth rates of the metal nanoparticles, the metal component of the metal nanoparticles, and the like.

In some embodiments, an amine surfactant or combination of amine surfactants, particularly aliphatic amines, can be present upon the metal nanoparticles. Amine surfactants can be particularly desirable for use in conjunction with copper nanoparticles. In some embodiments, two amine surfactants can be used in combination with one another. In other embodiments, three amine surfactants can be used in combination with one another. In more specific embodiments, a primary amine, a secondary amine, and a diamine chelating agent can be used in combination with one another. In still more specific embodiments, the three amine surfactants can include a long chain primary amine, a secondary amine, and a diamine having at least one tertiary alkyl group nitrogen substituent. Further disclosure regarding suitable amine surfactants follows hereinafter.

In some embodiments, the surfactant system can include a primary alkylamine. In some embodiments, the primary alkylamine can be a C₂-C₁₈ alkylamine. In some embodiments, the primary alkylamine can be a C₇-C₁₀ alkylamine. In other embodiments, a C₅-C₆ primary alkylamine can also be used. Without being bound by any theory or mechanism, the exact size of the primary alkylamine can be balanced between being long enough to provide an effective inverse micelle structure during synthesis versus having ready volatility and/or ease of handling during nanoparticle consolidation. For example, primary alkylamines with more than 18 carbons can also be suitable for use in the present embodiments, but they can be more difficult to handle because of their waxy character. C₇-C₁₀ primary alkylamines, in particular, can represent a good balance of desired properties for ease of use.

In some embodiments, the C₂-C₁₈ primary alkylamine can be n-hexylamine, n-heptylamine, n-octylamine, n-nonylamine, or n-decylamine, for example. While these are all straight chain primary alkylamines, branched chain primary alkylamines can also be used in other embodiments. For example, branched chain primary alkylamines such as, for example, 7-methyloctylamine, 2-methyloctylamine, or 7-methylnonylamine can be used. In some embodiments, such branched chain primary alkylamines can be sterically hindered where they are attached to the amine nitrogen atom. Non-limiting examples of such sterically hindered primary alkylamines can include, for example, t-octylamine, 2-methylpentan-2-amine, 2-methylhexan-2-amine, 2-methylheptan-2-amine, 3-ethyloctan-3-amine, 3-ethylheptan-3-amine, 3-ethylhexan-3-amine, and the like. Additional branching can also be present. Without being bound by any theory or mechanism, it is believed that primary alkylamines can serve as ligands in the metal coordination sphere but be readily dissociable therefrom during metal nanoparticle consolidation.

In some embodiments, the surfactant system can include a secondary amine. Secondary amines suitable for forming metal nanoparticles can include normal, branched, or cyclic C₄-C₁₂ alkyl groups bound to the amine nitrogen atom. In some embodiments, the branching can occur on a carbon atom bound to the amine nitrogen atom, thereby producing significant steric encumbrance at the nitrogen atom. Suitable secondary amines can include, without limitation, dihexylamine, diisobutylamine, di-t-butylamine, dineopentylamine, di-t-pentylamine, dicyclopentylamine, dicyclohexylamine, and the like. Secondary amines outside the C₄-C₁₂ range can also be used, but such secondary amines can have undesirable physical properties such as low boiling points or waxy consistencies that can complicate their handling.

In some embodiments, the surfactant system can include a chelating agent, particularly a diamine chelating agent. In some embodiments, one or both of the nitrogen atoms of the diamine chelating agent can be substituted with one or two alkyl groups. When two alkyl groups are present on the same nitrogen atom, they can be the same or different. Further, when both nitrogen atoms are substituted, the same or different alkyl groups can be present. In some embodiments, the alkyl groups can be C₁-C₆ alkyl groups. In other embodiments, the alkyl groups can be C₁-C₄ alkyl groups or C₃-C₆ alkyl groups. In some embodiments, C₃ or higher alkyl groups can be straight or have branched chains. In some embodiments, C₃ or higher alkyl groups can be cyclic. Without being bound by any theory or mechanism, it is believed that diamine chelating agents can facilitate metal nanoparticle formation by promoting nanoparticle nucleation.

In some embodiments, suitable diamine chelating agents can include N, N′-dialkylethylenediamines, particularly C₁-C₄ N,N′-dialkylethylenediamines. The corresponding methylenediamine, propylenediamine, butylenediamine, pentylenediamine or hexylenediamine derivatives can also be used. The alkyl groups can be the same or different. C₁-C₄ alkyl groups that can be present include, for example, methyl, ethyl, propyl, and butyl groups, or branched alkyl groups such as isopropyl, isobutyl, s-butyl, and t-butyl groups. Illustrative N,N′-dialkylethylenediamines that can be suitable for inclusion upon metal nanoparticles include, for example, N,N′-di-t-butylethylenediamine, N,N′-diisopropylethylenediamine, and the like.

In some embodiments, suitable diamine chelating agents can include N,N,N′,N′-tetraalkylethylenediamines, particularly C₁-C₄ N,N,N′,N′-tetraalkylethylenediamines. The corresponding methylenediamine, propylenediamine, butylenediamine, pentylenediamine or hexylenediamine derivatives can also be used. The alkyl groups can again be the same or different and include those mentioned above. Illustrative N,N,N′,N′-tetraalkylethylenediamines that can be suitable for use in forming metal nanoparticles include, for example, N,N,N′,N′-tetramethylethylenediamine, N,N,N′,N′-tetraethylethylenediamine, and the like.

Surfactants other than aliphatic amines can also be present in the surfactant system. In this regard, suitable surfactants can include, for example, pyridines, aromatic amines, phosphines, thiols, or any combination thereof. These surfactants can be used in combination with an aliphatic amine, including those described above, or they can be used in a surfactant system in which an aliphatic amine is not present. Further disclosure regarding suitable pyridines, aromatic amines, phosphines, and thiols follows below.

Suitable aromatic amines can have a formula of ArNR₁R₂, where Ar is a substituted or unsubstituted aryl group and R₁ and R₂ are the same or different. R₁ and R₂ can be independently selected from H or an alkyl or aryl group containing from 1 to about 16 carbon atoms. Illustrative aromatic amines that can be suitable for use in forming metal nanoparticles include, for example, aniline, toluidine, anisidine, N,N-dimethylaniline, N,N-diethylaniline, and the like. Other aromatic amines that can be used in conjunction with metal nanoparticles can be envisioned by one having ordinary skill in the art.

Suitable pyridines can include both pyridine and its derivatives. Illustrative pyridines that can be suitable for use inclusion upon metal nanoparticles include, for example, pyridine, 2-methylpyridine, 2,6-dimethylpyridine, collidine, pyridazine, and the like. Chelating pyridines such as bipyridyl chelating agents may also be used. Other pyridines that can be used in conjunction with metal nanoparticles can be envisioned by one having ordinary skill in the art.

Suitable phosphines can have a formula of PR₃, where R is an alkyl or aryl group containing from 1 to about 16 carbon atoms. The alkyl or aryl groups attached to the phosphorus center can be the same or different. Illustrative phosphines that can be present upon metal nanoparticles include, for example, trimethylphosphine, triethylphosphine, tributylphosphine, tri-t-butylphosphine, trioctylphosphine, triphenylphosphine, and the like. Phosphine oxides can also be used in a like manner. In some embodiments, surfactants that contain two or more phosphine groups configured for forming a chelate ring can also be used. Illustrative chelating phosphines can include 1,2-bisphosphines, 1,3-bisphosphines, and bis-phosphines such as BINAP, for example. Other phosphines that can be used in conjunction with metal nanoparticles can be envisioned by one having ordinary skill in the art.

Suitable thiols can have a formula of RSH, where R is an alkyl or aryl group having from about 4 to about 16 carbon atoms. Illustrative thiols that can present upon metal nanoparticles include, for example, butanethiol, 2-methyl-2-propanethiol, hexanethiol, octanethiol, benzenethiol, and the like. In some embodiments, surfactants that contain two or more thiol groups configured for forming a chelate ring can also be used. Illustrative chelating thiols can include, for example, 1,2-dithiols (e.g., 1,2-ethanethiol) and 1,3-dithiols (e.g., 1,3-propanethiol). Other thiols that can be used in conjunction with metal nanoparticles can be envisioned by one having ordinary skill in the art.

As mentioned above, a distinguishing feature of metal nanoparticles is their low fusion temperature, which may facilitate via filling to establish an effective thermal conduction pathway therein, according to the various embodiments of the present disclosure. In order to facilitate their disposition and formation of a monolithic metal body within the through-glass vias, the metal nanoparticles may be incorporated in a paste or similar formulation suitable for controlled introduction into the through-glass vias. Additional disclosure directed to metal nanoparticle paste compositions and similar formulations follows hereinbelow.

Metal nanoparticle paste compositions or similar formulations can be prepared by dispersing as-produced or as-isolated metal nanoparticles in an organic matrix containing one or more organic solvents and various other optional components. As used herein, the terms “nanoparticle paste formulation,” “nanoparticle paste composition” and grammatical equivalents thereof are used interchangeably and refer synonymously to a fluid composition containing dispersed metal nanoparticles that is suitable for dispensation using a desired technique. Use of the term “paste” does not necessarily imply an adhesive function of the paste alone. Through judicious choice of the organic solvent(s) and other additives, the loading of metal nanoparticles and the like, ready dispensation of the metal nanoparticles within one or more through-glass vias may be promoted.

Cracking can sometimes occur during consolidation of the metal nanoparticle and one way in which the nanoparticle pastes described herein can promote a decreased degree of cracking and void formation following metal nanoparticle consolidation is by maintaining a high solids content. More particularly, in some embodiments, the paste compositions can contain at least about 30% metal nanoparticles by weight, particularly about 30% to about 98% metal nanoparticles by weight of the paste composition, or about 50% to about 95% metal nanoparticles by weight of the paste composition, or about 70% to about 98% metal nanoparticles by weight of the paste composition. Moreover, in some embodiments, small amounts (e.g., about 0.01% to about 15% or about 35% or about 60% by weight of the paste composition) of micron-scale particles, particularly micron-scale metal particles, can be present in addition to the metal nanoparticles. Such micron-scale metal particles can desirably promote the fusion of metal nanoparticles into a contiguous mass (monolithic metal body) and further reduce the incidence of cracking. Instead of being liquefied and undergoing direct consolidation as is the case for the metal nanoparticles, the micron-scale metal particles can simply become joined together upon being contacted with liquefied metal nanoparticles that have been raised above their fusion temperature. These factors can reduce the porosity that results after fusing the metal nanoparticles together. The micron-scale metal particles can contain the same or different metals than the metal nanoparticles, and suitable metals for the micron-scale metal particles can include, for example, copper, silver, gold, aluminum, tin, and the like. Any of the foregoing micron-scale particles may serve as crack deflectors to limit propagation of cracks during use, thereby increasing mechanical strength.

Decreased cracking and void formation during metal nanoparticle consolidation can also be promoted by judicious choice of the solvent(s) forming the organic matrix. A tailored combination of organic solvents can desirably decrease the incidence of cracking and void formation. More particularly, an organic matrix containing one or more hydrocarbons (saturated, monounsaturated, polyunsaturated (2 or more double bonds) or aromatic), one or more alcohols, one or more amines, and one or more organic acids can be especially effective for this purpose. One or more esters and/or one or more anhydrides may be included, in some embodiments. Alkanolamines, such as ethanolamine, may also be present in some instances. Without being bound by any theory or mechanism, it is believed that this combination of organic solvents can facilitate the removal and sequestration of surfactant molecules surrounding the metal nanoparticles during consolidation, such that the metal nanoparticles can more easily fuse together with one another. More particularly, it is believed that hydrocarbon and alcohol solvents can passively solubilize surfactant molecules released from the metal nanoparticles by Brownian motion and reduce their ability to become re-attached thereto. In concert with the passive solubilization of surfactant molecules, amine and organic acid solvents can actively sequester the surfactant molecules through a chemical interaction such that they are no longer available for recombination with the metal nanoparticles.

Further tailoring of the solvent composition can be performed to reduce the suddenness of volume contraction that takes place during surfactant removal and metal nanoparticle consolidation. Specifically, more than one member of each class of organic solvent (i.e., hydrocarbons, alcohols, amines, and organic acids), optionally in combination with one or more alkanolamines, esters or anhydrides, can be present in the organic matrix, where the members of each class have boiling points that are separated from one another by a set degree. For example, in some embodiments, the various members of each class can have boiling points that are separated from one another by about 20° C. to about 50° C. By using such a solvent mixture, sudden volume changes due to rapid loss of solvent can be minimized during metal nanoparticle consolidation, since the various components of the solvent mixture can be removed gradually over a broad range of boiling points (e.g., about 50° C. to about 200° C.).

In various embodiments, at least some of the one or more organic solvents can have a boiling point of about 100° C. or greater. In other various embodiments, at least some of the one or more organic solvents can have a boiling point of about 200° C. or greater. In some or other embodiments, the one or more organic solvents can have boiling points ranging between about 50° C. and about 200° C., or between about 50° C. and about 250° C., or between about 50° C. and about 300° C., or between about 50° C. and about 350° C. Use of high boiling organic solvents can desirably increase the pot life of the metal nanoparticle paste compositions and limit the rapid loss of solvent, which can otherwise lead to cracking and void formation during nanoparticle consolidation. In some embodiments, at least one of the organic solvents can have a boiling point that is higher than the boiling point(s) of the surfactant(s) associated with the metal nanoparticles. Accordingly, surfactant(s) can be removed from the metal nanoparticles by evaporation before removal of the organic solvent(s) takes place.

In some embodiments, the organic matrix can contain one or more alcohols, which may be C₂-C₁₂, C₄-C₁₂ or C₇-C₁₂ in more particular embodiments. In various embodiments, the alcohols can include monohydric alcohols, diols, or triols. One or more glycol ethers (e.g., diethylene glycol and triethylene glycol), alkanolamines (e.g., ethanolamine, triethanolamine, and the like), or any combination thereof may be present in certain embodiments, which may be present alone or in combination with other alcohols. Various glymes may be present with the one or more alcohols in some embodiments. In some embodiments, one or more hydrocarbons can be present in combination with one or more alcohols. As discussed above, it is believed that alcohol (and optionally glymes and alkanolamines) and hydrocarbon solvents can passively promote the solubilization of surfactants as they are removed from the metal nanoparticles by Brownian motion and limit their re-association with the metal nanoparticles. Moreover, hydrocarbon and alcohol solvents only weakly coordinate with metal nanoparticles, so they do not simply replace the displaced surfactants in the nanoparticle coordination sphere. Illustrative but non-limiting examples of alcohol and hydrocarbon solvents that can be present include, for example, light aromatic petroleum distillate (CAS 64742-95-6), hydrotreated light petroleum distillates (CAS 64742-47-8), tripropyleneglycol methyl ether, ligroin (CAS 68551-17-7, a mixture of C10-C13 alkanes), diisopropyleneglycol monomethyl ether, diethyleneglycol diethyl ether, 2-propanol, 2-butanol, t-butanol, 1-hexanol, 2-(2-butoxyethoxy)ethanol, and terpineol. In some embodiments, polyketone solvents can be used in a like manner.

In some embodiments, the organic matrix can contain one or more amines and one or more organic acids. In some embodiments, the one or more amines and one or more organic acids can be present in an organic matrix that also includes one or more hydrocarbons and one or more alcohols. As discussed above, it is believed that amines and organic acids can actively sequester surfactants that have been passively solubilized by hydrocarbon and alcohol solvents, thereby making the surfactants unavailable for re-association with the metal nanoparticles. Thus, an organic solvent that contains a combination of one or more hydrocarbons, one or more alcohols, one or more amines, and one or more organic acids can provide synergistic benefits for promoting the consolidation of metal nanoparticles. Illustrative but non-limiting examples of amine solvents that can be present include, for example, tallowamine (CAS 61790-33-8), alkyl (C₈-C₁₈) unsaturated amines (CAS 68037-94-5), di(hydrogenated tallow)amine (CAS 61789-79-5), dialkyl (C₅-C₂₀) amines (CAS 68526-63-6), alkyl (C₁₀-C₁₆)dimethyl amine (CAS 67700-98-5), alkyl (C₁₄-C₁₈) dimethyl amine (CAS 68037-93-4), dihydrogenated tallowmethyl amine (CAS 61788-63-4), and trialkyl (C₆-C₁₂) amines (CAS 68038-01-7). Illustrative but non-limiting examples of organic acid solvents that can be present in the nanoparticle paste compositions include, for example, octanoic acid, nonanoic acid, decanoic acid, caprylic acid, pelargonic acid, undecylic acid, lauric acid, tridecylic acid, myristic acid, pentadecanoic acid, palmitic acid, margaric acid, stearic acid, nonadecylic acid, a-linolenic acid, stearidonic acid, oleic acid, and linoleic acid.

In some embodiments, the organic matrix can include more than one hydrocarbon, more than one alcohol, optionally more than one glyme (glycol ether), more than one amine, and more than one organic acid. For example, in some embodiments, each class of organic solvent can have two or more members, or three or more members, or four or more members, or five or more members, or six or more members, or seven or more members, or eight or more members, or nine or more members, or ten or more members. Moreover, the number of members in each class of organic solvent can be the same or different. Particular benefits of using multiple members of each class of organic solvent are described herein.

One particular advantage of using multiple members within each class of organic solvent is the ability to provide a wide spread of boiling points in the metal nanoparticle paste compositions. By providing a wide spread of boiling points, the organic solvents can be removed gradually as the temperature rises while affecting metal nanoparticle consolidation, thereby limiting volume contraction and disfavoring cracking. By gradually removing the organic solvent in this manner, less temperature control may be needed to affect slow solvent removal than if a single solvent with a narrow boiling point range was used. In some embodiments, the members within each class of organic solvent can have a window of boiling points ranging between about 50° C. and about 200° C., or between about 50° C. and about 250° C., or between about 100° C. and about 200° C., or between about 100° C. and about 250° C., or between about 150° C. and about 300° C., or between about 150° C. and about 350° C. In more particular embodiments, the various members of each class of organic solvent can each have boiling points that are separated from one another by at least about 20° C., specifically about 20° C. to about 50° C. More specifically, in some embodiments, each hydrocarbon can have a boiling point that differs by about 20° C. to about 50° C. from other hydrocarbons in the organic matrix, each alcohol can have a boiling point that differs by about 20° C. to about 50° C. from other alcohols in the organic matrix, each amine can have a boiling point that differs by about 20° C. to about 50° C. from other amines in the organic matrix, and each organic acid can have a boiling point that differs by about 20° C. to about 50° C. from other organic acids in the organic matrix. The more members of each class of organic solvent that are present, the smaller the differences become between the boiling points. By having smaller differences between the boiling points, solvent removal can be made more continual, thereby limiting the degree of volume contraction that occurs at each stage. A reduced degree of cracking can occur when at least four or five (or more) members of each class of organic solvent are present (e.g., four or more hydrocarbons, four or more alcohols, four or more amines, and four or more organic acids; or five or more hydrocarbons, five or more alcohols, five or more amines, and five or more organic acids), each having boiling points that are separated from one another within the above range as described herein.

As discussed above, a suitable CTE modifiers may also be added to the composition including, but not limited to, diamond particles, graphite/pitch-based carbon fibers (e.g., having a diameter of about 10 microns), tungsten particles, molybdenum particles, diamond particles, boron nitride particles, boron carbide particles, aluminum nitride particles, silicon, carbon nanotubes, graphene, the like, and any combination thereof. Carbon-based additives, for example, can achieve about 2-3 ppm thermal expansion when added at about 16% by volume, or about 7 ppm thermal expansion when added at about 9% by volume, or about 6 ppm when added at about 11% by volume. Based thereon, in some embodiments, micron-scale graphite particles or carbon fibers or carbon nanotubes may also be included. Diamond particles, and/or graphene may also be included, in some embodiments.

In some embodiments, suitable nanoparticle paste compositions may further comprise diamond particles. A suitable size of diamond particles may be dictated by the size of the via to be filled. In general, diamond particles smaller in size than the diameter of the via may be selected so that the diamond particles can successfully enter the via. The size of the diamond particles may remain sufficiently small such that dispensability of the metal nanoparticle paste composition is not compromised.

Nanoparticle paste compositions suitable for use in filling opening including through-glass vias, blind vias, conduits, trenches, and other openings and apertures in glass interposers and other similar glass substrate according to the present disclosure can be formulated using any of the metal nanoparticle paste compositions described hereinabove. In addition, according to some embodiments, multiple metals may be present in the metal nanoparticle paste compositions. In some or other embodiments, suitable metal nanoparticle paste compositions can include a mixture of metal nanoparticles, other nano-sized particles (i.e., particles having a dimension of about 100 nm or less), and/or micron-scale particles, including micron-scale metal particles. The metal nanoparticle paste compositions may comprise copper nanoparticles, according to more specific embodiments.

In some embodiments of the present disclosure, through-glass vias are filled with metal nanoparticles, which undergo subsequent consolidation to form a monolithic metal body in each through-glass via. The metal nanoparticles may be contained within a metal nanoparticle paste composition, such as a metal nanoparticle paste composition comprising copper nanoparticles. The metal nanoparticle paste composition is subsequently processed to promote at least partial consolidation of the metal nanoparticles within the vias to form a monolithic metal body (i.e., a continuous mass of bulk metal) that fills the vias and extends between opposing faces of the glass interposer. For example, according to various embodiments, the metal nanoparticles may be heated at or above the fusion temperature while located within the via to form the monolithic metal body therein. Alternately, pressure may be applied to promote metal nanoparticle consolidation within the vias. The vias and the monolithic metal bodies extend between the first and second faces of the glass interposer to provide an electrical connection between the integrated circuit substrate and one or more chiplets.

Suitable through-glass vias may have any cross-sectional profile as they extend through the glass interposer. According to some embodiments, the through-glass vias may have a round cross-sectional profile; thus, such vias have a cylindrical shape. Other suitable via cross-sectional profiles include, but are not limited to, square, rectangular, triangular, ovular, or other regular or irregular geometric shapes. The cross-sectional profile of the vias may be substantially equal in size upon both faces of the glass interposer, or the cross-sectional profiles may differ in size, according to some embodiments as describe above.

In more particular embodiments, the monolithic metal body may comprise copper and be formed from copper nanoparticles.

In some or other more particular embodiments, the monolithic metal body may further comprise other types of highly conductive particles (e.g., carbon nanotubes, graphene, or the like).

Methods of the present disclosure may comprise providing a glass interposer having one or more vias extending therebetween a first face and a second face, filling the one or more vias with a metal nanoparticle paste composition, and consolidating metal nanoparticles of the metal nanoparticle paste composition within the one or more vias to form a monolithic metal body filling each of the one or more vias. The metal nanoparticles may comprise copper nanoparticles in more specific embodiments of the present disclosure. The metal nanoparticle paste composition may be adapted to limit shrinkage during consolidation in particular embodiments of the present disclosure, as referenced above. Walls of the one or more vias may have a coating thereon to promote adherence of the monolithic metal body.

In various embodiments, consolidating the metal nanoparticles may comprise heating the metal nanoparticles above the fusion temperature, applying pressure to the metal nanoparticles, or any combination thereof. Any heat source may be used to heat the metal nanoparticles above the fusion temperature, such as an oven, autoclave, heating tape, radiant heat source, laser, photosintering or the like. In some embodiments, direct laser sintering of the metal nanoparticles within the vias may take place. Other techniques for consolidating the metal nanoparticles within the vias may include, for example, applying pressure with a heated piston from one or both faces of the PCB to affect heating and compaction simultaneously. The consolidated metal nanoparticles may have a nano-sized grain structure ranging from about 100 nm to about 500 nm in size and a porosity ranging from about 2% to about 12% by volume. Further sintering following metal nanoparticle consolidation may achieve a porosity ranging from 0% (fully dense) to about 2% by volume, which may approach the conductivity of bulk metal (copper).

According to the disclosure herein, the walls of the vias may be plated with a metal prior to filling the vias with the metal nanoparticle paste composition. The metal plating on the walls of the vias may promote adhesion of the glass interposer to the monolithic metal body following metal nanoparticle consolidation and can result in a hermetic seal. Electrodeposition techniques, such as electroless plating, for example, may be used in particular embodiments to affect metal plating upon the walls of the vias. The metal plating on the walls of the vias may be the same as or different than a metal comprising the monolithic metal bodies. A metal plating containing a metal differing from the monolithic metal body may be especially desirable when a metal comprising the monolithic metal body insufficiently adheres to the glass interposer, which comprises the walls of the vias. A metal differing from the metal comprising the monolithic metal body may form an intermetallic layer that provides a transition between the monolithic metal body and the via walls.

In the particular case of copper nanoparticles and a monolithic metal body formed therefrom, a tin coating upon the walls of the vias may promote ready adherence of the monolithic metal body. Suitable conditions for electrodepositing tin will be familiar to one having ordinary skill in the art. In illustrative embodiments, electrodeposition of tin may take place by an electroless plating technique. Electroless plating of tin may be conducted by reacting a solution of a tin salt with a reducing agent such as borohydride, for example, within the one or more vias. Other suitable conditions for electroplating tin may also be suitably used. The tin coating may have a thickness ranging from about 100 nm to about 500 nm, or about 250 nm to about 750 nm, or about 400 nm to about 2 microns, for example.

Besides tin, other metals or metalloids that may be coated on the via walls when filling the vias with copper nanoparticles include, for example, bismuth, gallium, zinc, tin solder alloys, “white” or “Babbit” alloys having a melting point below about 260° C., selenium, or indalloys. Tin and alternative metals or metalloids may or may not melt when being co-processed with copper nanoparticles.

Gallium may comprise a particularly suitable alternative substance for forming a coating, since it readily wets many metallic and non-metallic surfaces, such as glass and ceramics, and expands when solidifying, thereby mitigating the shrinkage of copper when forming a monolithic metal body. Zinc may form a strong brass intermediate layer upon the walls of the via. As such, tin, gallium and zinc may facilitate direct bonding of a monolithic metal body to ceramic and glass substrates, including glass interposers, with good adhesion thereto.

Any of the foregoing alternative metals or metalloids may also be electrodeposited within the vias when suitable electrodeposition conditions can be identified. More conveniently, metals, metal alloys, and metalloids may be introduced as a coating within the vias simply dipping the glass interposer in a molten metal, metal alloy, or metalloid, or by applying the metal, metal alloy, or metalloid as a liquid via a hot tip device, such as a soldering iron or the like. The low melting points of these metals and metalloids may allow deposition to take place without harming the glass interposer. Tin may also be suitably deposited in this regard. Wave soldering may be used to deposit any of the coating materials upon the via walls. Tin, alternative metals or metalloids may also be applied to vias after copper nanoparticles have been introduced thereto, but before the copper nanoparticles have undergone consolidation. Intimate mixing of the metal or metalloid in the contact region between copper nanoparticles and the via walls may be realized by this approach. The contact region at the via walls may be about 10 nm to about 100 nm in thickness, or about 50 nm to about 250 nm in thickness, or about 200 nm to about 750 nm in thickness, or about 500 nm to about 1.5 microns in thickness. As such, an elongate consolidated metal body may be formed in the vias, wherein the elongate consolidated metal body is surrounded by a thin shell of metal or metalloid, such as tin, or an intermetallic compound formed therefrom that improves adherence to the via walls.

The present application will now be described with reference to the following non-limiting examples:

### Example 1

A square glass substrate 375 micron thick with a CTE of 5.4 ppm (room temperature to 150° C.) and with an area of 4 in 2 containing 40,000 circular vias arranged in a square is filled using 3.5 g of a copper nanoparticle paste composition with a density of 6.17 g/cm³ and a final CTE after fusion of 8.1. The vias exhibit an hour-glass shape produced by lasering into the glass substrate from both sides. The via opening diameters of both top and bottom start at 80 microns and slim down at the center to a 65 micron size neck. The pitch between each via is 100 microns in all directions.

The glass is first cleaned with ethanol to remove any surface contamination followed by the paste application using a stiff silicone squeegee at a forward angle of approximately 20-35 degrees.

Fusion process: after via fill, the part is placed into a suitable hot press that was preheated to 60° C. followed by the application of a pressure of 750 psi. The temperature is ramped to 230° C. over 15 min and held for another 45 min, then the pressure released and cooled down at a rate of no more than 10° C. per minute.

Most of the through-glass vias were observed to adhere well to the walls of the glass substrate with only some small voids detectible, but no cracks or other defects were observed.

### Example 2

A round glass wafer 435 micron thick with a 7.5 cm large diameter and a CTE of 3.2 ppm (room temperature to 150° C.) containing 28,900 circular vias arranged in a square is filled using 2 g of a copper nanoparticle paste composition with a density of 6.3 g/cm³ and a final CTE of the fused copper fill of 5.7 ppm. The vias exhibit a tapered shape produced by first laser treating the glass from one side followed by wet-etching using a suitable hydrofluoric acid solution. The via opening diameter at the top is about 85 microns and slims down to a 70 micron size bottom opening. The pitch between each via is 150 microns.

The glass is first cleaned with ethanol to remove any surface contamination followed by the paste application using a stiff silicone squeegee at a forward angle of approximately 20-35 degrees.

Fusion process: after via fill, the part is placed on a carrier and run through a conveyor belt type reflow oven at atmospheric pressure and a nitrogen atmosphere containing no more than 65 ppm oxygen. The profile is set such that a temperature ramp to 240° C. in 3 min is achieved and held for another 5 min at that temperature and then cooled down to room temperature. before taking it out of the oven.

Most of the through-glass vias were observed to adhere well to the walls of the glass substrate with only some small voids detectible, but no cracks or other defects were observed.

### Example 3

A square glass substrate 550 micron thick with a CTE of 5.7 ppm (room temperature to 150° C.) and with an area of 4 in 2 containing 20,000 circular vias of two different sizes and 10 trenches is filled using 3.5 g of a copper nanoparticle paste composition with a density of 6.17 g/cm³ and a final CTE after fusion of 6.9. The vias exhibit an hour-glass shape produced by lasering into the glass substrate from both sides. The via opening diameters of type one start at 80 microns (top and bottom) and slim down at the center to a 65 micron size neck. Type two exhibit openings of 150 micrometer and slim down at the center to 130 micron. The pitch between each via is 100 microns in all directions. The trenches are 100 micron deep, 500 micron wide and 10 mm long.

The glass is first cleaned with ethanol to remove any surface contamination followed by the paste application using a stiff silicone squeegee at a forward angle of approximately 20-35 degrees.

Fusion process: after via fill, the part is placed into a suitable hot press that was preheated to 60° C. followed by the application of a pressure of 750 psi. The temperature is ramped to 230° C. over 15 min and held for another 45 min, then the pressure released and cooled down at a rate of no more than 10° C. per minute.

Most of the through-glass vias were observed to adhere well to the walls of the glass substrate with only some small voids detectible, but no cracks or other defects were observed.

The present disclosure provides an entirely different approach for filling through-glass vias, other apertures, blind vias, and other similar conduits in a glass substrate to establish one or more electrically conduction pathways extending through the glass substrate to provide electrical connection therebetween. Advantageously, the via-filling approaches described herein may be performed rapidly and at much lower cost than other approaches, including wholly electrodeposition approaches, while still readily affording high-quality and reliable electrically conductive monolithic metal bodies that extend completely through the glass substrate. Although the present disclosure is largely directed to the filling of through-glass vias, it is to be appreciated that alternative structures may be processed analogously.

### Additional Embodiments

Clause 1: A glass substrate comprising one or more openings therein, wherein the one or more openings comprise one or more through-glass vias, wherein the one or more openings are metallized with a bulk metal matrix formed from fusion of metal nanoparticles or a reaction product formed from metal nanoparticles.
Clause 2: The glass substrate according to Clause 1, wherein the metal nanoparticles comprise electrically conductive nanoparticles.
Clause 3: The glass substrate according to Clause 2, wherein the electrically conductive nanoparticles are selected from the group consisting of copper, silver, gold, and combinations of one or more of the foregoing.
Clause 4: The glass substrate according to Clause 2 or Clause 3, wherein the electrically conductive nanoparticles comprise copper nanoparticles.
Clause 5: The glass substrate according to Clause 4, wherein the copper nanoparticles are formulated in a copper nanoparticle paste composition comprising the copper nanoparticles and micron-scale metal particles.
Clause 6: The glass substrate according to Clause 5, wherein the copper nanoparticle paste composition further comprises a coefficient of thermal expansion (CTE) modifier, wherein the CTE modifier is capable of lowering the CTE of the copper nanoparticle paste composition.
Clause 7: The glass substrate according to any of Clauses 1 to 4, wherein a thickness of the glass substrate is from about 25 μm and about 1 mm.
Clause 8: The glass substrate according to any of Clauses 1 to 7, wherein the one or more through-glass vias have an hourglass shape, a cylindrical shape, a tapered cylindrical shape, a conical shape, or combinations thereof.
Clause 9: The glass substrate according to Clause 8, wherein a largest diameter of the one or more through-glass vias is between about 10 μm and about 350 μm.
Clause 10: The glass substrate according to any of Clauses 1 to 7, wherein the one or more openings further comprise one or more blind vias.
Clause 11: The glass substrate according to any of Clauses 1 to 10, wherein the one or more openings comprise a metal coating on walls of the one or more openings to promote adhesion of the glass substrate to the bulk metal matrix following nanoparticle consolidation, optionally wherein the adhesion results in a hermetic seal.
Clause 12: The glass substrate according to any of Clauses 1 to 10, wherein the one or more openings further comprise one or more trenches, conduits, apertures, or other openings arranged therein.
Clause 13: The glass substrate according to any of Clauses 1 to 11, wherein the through-glass vias have an aspect ratio of between about 0.5:1and about 15:1.
Clause 14: The glass substrate according to any of Clauses 1 to 11, wherein the through-glass vias are arranged in an array, wherein a pitch between a centerline of one through-glass via to any other through-glass via is between about 10 μm and about 2,000 μm.
Clause 15: The glass substrate according to any of Clauses 1 to 14, wherein at least a plurality of the through-glass vias have substantially the same largest diameter and a pitch between a centerline of one through-glass via to any other through-glass via is substantially the same size as the largest diameter of the through-glass vias.
Clause 16: The glass substrate according to any of Clauses 1 to 11, wherein the largest diameter of through-glass vias is at least 5X greater in size than the diameter of the largest size particles in the nanoparticle paste composition.
Clause 17: The glass substrate according to any of Clauses 1 to 11, wherein the coefficient of thermal expansion (CTE) of the glass substrate at least substantially matches the CTE of the bulk metal matrix formed from fusion of the metal nanoparticles or a reaction product formed form metal nanoparticles.
Clause 18: The glass substrate according to Clause 17, wherein the CTE of the bulk metal matrix is between about 3 ppm and about 12 ppm.
Clause 19: A method of making a metallized glass interposer for use in an integrated circuit packaging solution, the method comprising the steps of:
   a. providing a glass substrate comprising a plurality of through-glass vias, blind vias, and/or other openings arranged therein;
   b. applying a copper nanoparticle paste composition to the glass substrate to fill the plurality through-glass vias, blind vias, and/or other openings arranged therein with the copper nanoparticle paste composition;
   c. consolidating the copper nanoparticle paste composition to form a bulk copper matrix within the plurality of through-glass vias, blind vias, and/or other openings, wherein the bulk copper matrix has a conductivity of at least 50% IACS.
Clause 20: The method according to Clause 19, wherein the copper nanoparticle paste composition comprises copper nanoparticles and micron-scale metal particles.
Clause 21: The method according to Clause 20, wherein the copper nanoparticle paste composition further comprises a coefficient of thermal expansion (CTE) modifier, wherein the CTE modifier is capable of lowering the CTE of the copper nanoparticle paste composition to less than about 5 ppm, preferably less than about 4 ppm, most preferably less than about 3 ppm.
Clause 22: The method according to any of Clauses 19 to 21, wherein the step of consolidating the copper nanoparticle paste composition to form the bulk copper matrix comprises heating the copper nanoparticle paste composition to a temperature of between about 140° C. and about 240° C. for a sufficient period of time to cause the metal nanoparticles to undergo liquefication.
Clause 23: A packaging system comprising:
   a. a substrate;
   b. one or more glass interposers arranged on the substrate, wherein the one or more glass interposers are electrically connected to the substrate, wherein the one or more glass interposers comprises an array of metallized through-glass vias; and
   c. a plurality of chiplets arranged on the one or more glass interposers, wherein the chiplets are electrically connected to the one or more glass interposers;
   wherein the through-glass vias are metallized with a bulk matrix formed from at least partial fusion or consolidation of metal nanoparticles or a reaction product formed from metal nanoparticles.
Clause 24: The packaging system according to Clause 23, wherein the packaging system comprises a 2.5D packaging system, a 3D packaging system, or a combination of a 2.5D and a 3D packaging system.

What is claimed is:

1. A glass substrate comprising one or more openings therein, wherein the one or more openings comprise one or more through-glass vias, wherein the one or more openings are metallized with a bulk metal matrix formed from fusion of metal nanoparticles or a reaction product formed from metal nanoparticles.

2. The glass substrate according to claim 1, wherein the metal nanoparticles comprise electrically conductive nanoparticles.

3. The glass substrate according to claim 2, wherein the electrically conductive nanoparticles are selected from the group consisting of copper, silver, gold, and combinations of one or more of the foregoing.

4. The glass substrate according to claim 2, wherein the electrically conductive nanoparticles comprise copper nanoparticles.

5. The glass substrate according to claim 4, wherein the copper nanoparticles are formulated in a copper nanoparticle paste composition comprising the copper nanoparticles and micron-scale metal particles.

6. The glass substrate according to claim 5, wherein the copper nanoparticle paste composition further comprises a coefficient of thermal expansion (CTE) modifier, wherein the CTE modifier is capable of lowering the CTE of the copper nanoparticle paste composition.

7. The glass substrate according to claim 1, wherein a thickness of the glass substrate is from about 25 μm and about 1 mm.

8. The glass substrate according to claim 1, wherein the one or more through-glass vias have an hourglass shape, a cylindrical shape, a tapered cylindrical shape, a conical shape, or combinations thereof.

9. The glass substrate according to claim 8, wherein a largest diameter of the one or more through-glass vias is between about 10 μm and about 350 μm.

10. The glass substrate according to claim 1, wherein the one or more openings further comprise one or more blind vias.

11. The glass substrate according to any of claim 10, wherein the one or more openings comprise a metal coating on walls of the one or more openings to promote adhesion of the glass substrate to the bulk metal matrix following nanoparticle consolidation, optionally wherein the adhesion results in a hermetic seal.

12. The glass substrate according to claim 10, wherein the one or more openings further comprise one or more trenches, conduits, apertures, or other openings arranged therein.

13. The glass substrate according to claim 1, wherein the through-glass vias have an aspect ratio of between about 0.5:1and about 15:1.

14. The glass substrate according claim 1, wherein the through-glass vias are arranged in an array, wherein a pitch between a centerline of one through-glass via to any other through-glass via is between about 10 μm and about 2,000 μm.

15. The glass substrate according to claim 14, wherein at least a plurality of the through-glass vias have substantially the same largest diameter and a pitch between a centerline of one through-glass via to any other through-glass via is substantially the same size as the largest diameter of the through-glass vias.

16. The glass substrate according to claim 1, wherein the largest diameter of through-glass vias is at least 5X greater in size than the diameter of the largest size particles in the nanoparticle paste composition.

17. The glass substrate according to claim 1, wherein the coefficient of thermal expansion (CTE) of the glass substrate at least substantially matches the CTE of the bulk metal matrix formed from fusion of the metal nanoparticles or a reaction product formed form metal nanoparticles.

18. The glass substrate according to claim 17, wherein the CTE of the bulk metal matrix is between about 3 ppm and about 12 ppm.

19. A method of making a metallized glass interposer for use in an integrated circuit packaging solution, the method comprising the steps of:
a. providing a glass substrate comprising a plurality of through-glass vias, blind vias, and/or other openings arranged therein;
b. applying a copper nanoparticle paste composition to the glass substrate to fill the plurality through-glass vias, blind vias, and/or other openings arranged therein with the copper nanoparticle paste composition;
c. consolidating the copper nanoparticle paste composition to form a bulk copper matrix within the plurality of through-glass vias, blind vias, and/or other openings, wherein the bulk copper matrix has a conductivity of at least 50% IACS.

20. The method according to claim 19, wherein the copper nanoparticle paste composition comprises copper nanoparticles and micron-scale metal particles.

21. The method according to claim 20, wherein the copper nanoparticle paste composition further comprises a coefficient of thermal expansion (CTE) modifier, wherein the CTE modifier is capable of lowering the CTE of the copper nanoparticle paste composition to less than about 5 ppm, preferably less than about 4 ppm, most preferably less than about 3 ppm.

22. The method according to claim 19, wherein the step of consolidating the copper nanoparticle paste composition to form the bulk copper matrix comprises heating the copper nanoparticle paste composition to a temperature of between about 140° C. and about 240° C. for a sufficient period of time to cause the metal nanoparticles to undergo liquefication.

23. A packaging system comprising:
a. a substrate;
b. one or more glass interposers arranged on the substrate, wherein the one or more glass interposers are electrically connected to the substrate, wherein the one or more glass interposers comprises an array of metallized through-glass vias; and
c. a plurality of chiplets arranged on the one or more glass interposers, wherein the chiplets are electrically connected to the one or more glass interposers;
wherein the through-glass vias are metallized with a bulk matrix formed from at least partial fusion or consolidation of metal nanoparticles or a reaction product formed from metal nanoparticles.

24. The packaging system according to claim 23, wherein the packaging system comprises a 2.5D packaging system, a 3D packaging system, or a combination of a 2.5D and a 3D packaging system.
